(19) United States
(12) Patent Application Publication
(10) Pub. No.: US 2014/0346667 A1
(43) Pub. Date: Nov. 27, 2014

(54) SEMICONDUCTOR PACKAGE AND METHOD OF FABRICATING THE SAME

(71) Applicants: Seunghun HAN, Asan-si (KR); Sang-Uk KIM, Cheonan-si (KR); CHOONGBIN YIM, Cheonan-si (KR)

(72) Inventors: Seunghun HAN, Asan-si (KR); Sang-Uk KIM, Cheonan-si (KR); CHOONGBIN YIM, Cheonan-si (KR)

(21) Appl. No.: 14/210,344

(22) Filed: Mar. 13, 2014

(30) Foreign Application Priority Data
May 27, 2013 (KR) 10-2013-0059853

(51) Int. Cl. H01L 25/04; H01L 23/00

(52) U.S. Cl. CPC H01L 25/04; H01L 24/03; H01L 24/06; H01L 24/14
USPC 257/737; 438/107; 257/773

(57) ABSTRACT

A semiconductor package comprising: a lower semiconductor package comprising a lower semiconductor chip mounted on a lower package substrate and a lower molding layer substantially covering the lower semiconductor chip and having through holes arranged in a first direction and a second direction. The first direction is different from the second direction; and for each of the through holes, first and second upper widths of the through hole in the first and second directions are less than a third upper width of the through hole in a third direction that is a diagonal direction with respect to the first and second directions.

### CROSS-REFERENCE TO RELATED APPLICATIONS

This U.S. non-provisional patent application claims priority under 35 U.S.C. §119 of Korean Patent Application No. 10-2013-0059853, filed on May 27, 2013, the entire contents of which are hereby incorporated by reference.

### BACKGROUND

This disclosure relates to a semiconductor package, and more particularly, to a package on package (PoP) type semiconductor package and a method of fabricating the same.

In the semiconductor industry, as a demand for semiconductor devices and high capacity, reduced-size, and miniaturized electronic products using the same increases, various package technologies are being developed. Recently developed semiconductor package, in which semiconductor chips having various functions may be integrated in areas less than those of general packages including one semiconductor chip.

A package on package (PoP) technology where a package is stacked on the other package was proposed to laminate a plurality of semiconductor chips on each other and to realize a high density chip lamination. In the PoP technology, each of the semiconductor chips may pass a test. As a result, a defect rate for the final products may decrease. These PoP type semiconductor packages may be used to satisfy miniaturization of electronic portable devices and functional diversification of mobile products.

### SUMMARY

An embodiment includes a semiconductor package comprising: a lower semiconductor package comprising a lower semiconductor chip mounted on a lower package substrate and a lower molding layer substantially covering the lower semiconductor chip and having through holes arranged in a first direction and a second direction. The first direction is different from the second direction; and for each of the through holes, first and second upper widths of the through hole in the first and second directions are less than a third upper width of the through hole in a third direction that is a diagonal direction with respect to the first and second directions.

Another embodiment includes a method of fabricating a semiconductor package, the method comprising: forming a molding layer on a lower package substrate on which a lower semiconductor chip is mounted, wherein the lower package substrate comprises lower connections arranged in a first direction and a second direction different from the first direction; forming first openings associated with the lower connections in the molding layer, each first opening disposed along a third direction relative to the corresponding lower connection that is a diagonal direction with respect to the first and second directions; and forming second openings exposing the lower connections, each first opening overlapping the second opening exposing the corresponding lower connection.

Another embodiment includes a semiconductor package, comprising: a package substrate including a plurality of connection pads; a molding layer disposed on the package substrate; and a plurality of through holes in the molding layer exposing corresponding connection pads, each through hole comprising: a first opening; and a second opening; wherein the first opening is disposed along a side surface of the second opening and extends along less than all of the side surface of the second opening.

### BRIEF DESCRIPTION OF THE DRAWINGS

The accompanying drawings are included to provide a further understanding of the embodiments, and are incorporated in and constitute a part of this specification. The drawings illustrate exemplary embodiments and, together with the description, serve to explain principles of the embodiments. In the drawings:

FIG. 1A is a plan view illustrating a semiconductor package according to an embodiment, and FIG. 1B is a cross-sectional view taken along line I-I′ of FIG. 1A;

FIG. 2A is a plan view illustrating a semiconductor package according to another embodiment, and FIG. 2B is a cross-sectional view taken along line I-I′ of FIG. 2A;

FIGS. 3A to 3E are cross-sectional views illustrating a method of fabricating an upper package according to an embodiment;

FIGS. 4A to 9A and 11A are plan views illustrating a method of fabricating a lower package according to an embodiment;

FIGS. 4B to 9B and 11B are cross-sectional views illustrating the method of fabricating the lower package according to an embodiment, taken along line I-I′ of FIGS. 4A to 9A and 11A;

FIG. 10 is an enlarged plan view of a section A of FIG. 9A, which illustrates the method of fabricating the lower package according to an embodiment;

FIG. 12 is an enlarged plan view of a section B of FIG. 11A, which illustrates the method of fabricating the lower package according to an embodiment;

FIGS. 13 and 14 are cross-sectional views illustrating the method of fabricating the lower package according to an embodiment;

FIG. 15 is an enlarged plan view of the section B of FIG. 11A, which illustrates a method of fabricating a lower package according to another embodiment;

FIG. 16 is an enlarged plan view of the section B of FIG. 11A, which illustrates a method of fabricating a lower package according to further another embodiment;

FIGS. 17A and 18A are cross-sectional views illustrating a method of fabricating a lower package according to another embodiment, and FIGS. 17B and 18B are cross-sectional views taken along line I-I′ of FIGS. 17A and 18A;

FIG. 19 is a view illustrating an electronic device to which the lamination type semiconductor packages according to an embodiment are applied; and

FIG. 20 is a schematic block diagram illustrating an electronic device to which the lamination type semiconductor packages according to an embodiment are applied.

### DETAILED DESCRIPTION OF THE EMBODIMENTS

Advantages, features, and implementation methods according to various embodiments will be clarified through the following embodiments described with reference to the accompanying drawings. Embodiments may, however, take different forms and should not be construed as limited to the particular embodiments set forth herein. Rather, these embodiments are provided so that this disclosure will be thorough and complete, and will fully convey the scope of the claims to those skilled in the art. Like reference numerals refer to like elements throughout.

In the following description, the technical terms are used only for explaining a particular embodiment and may or may not limit other embodiments. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

Additionally, the embodiments in the detailed description will be described with sectional views and/or plan views as ideal exemplary views. In the figures, the dimensions of layers and regions may be exaggerated for clarity of illustration. Accordingly, shapes of the exemplary views may be modified according to manufacturing techniques and/or allowable errors. Therefore, the embodiments may or may not be limited to the specific shape illustrated in the exemplary views, but may include other shapes that may be created according to manufacturing processes. For example, an etching area illustrated at a right angle may have a round shape or a predetermined curvature. Areas exemplified in the drawings have general properties, and are used to illustrate a specific shape of a semiconductor package region. Thus, this should not be construed as limited to the scope of embodiments.

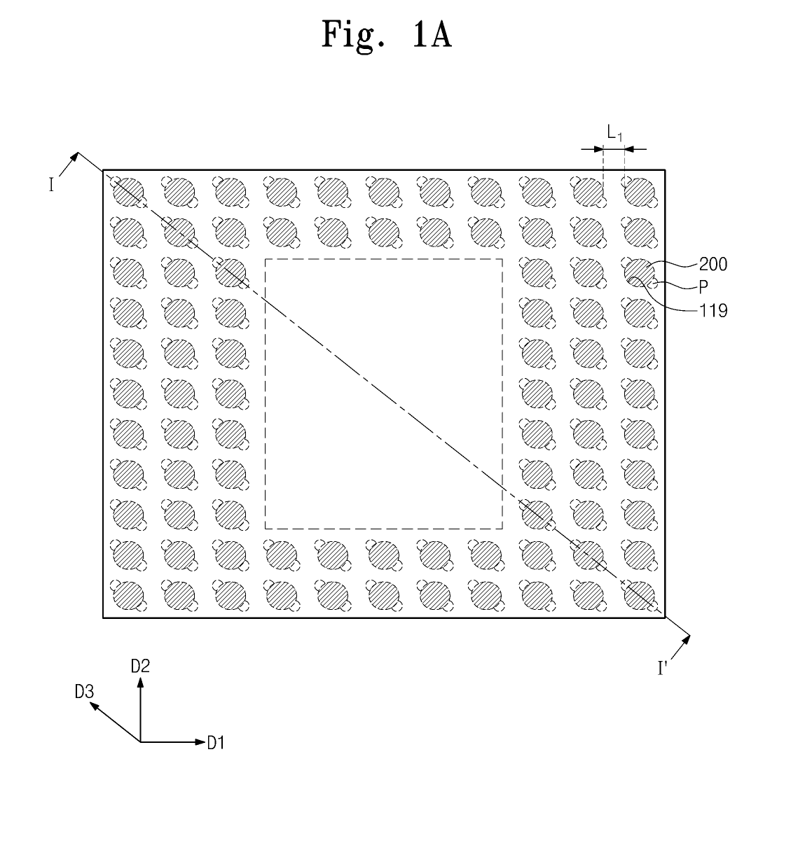

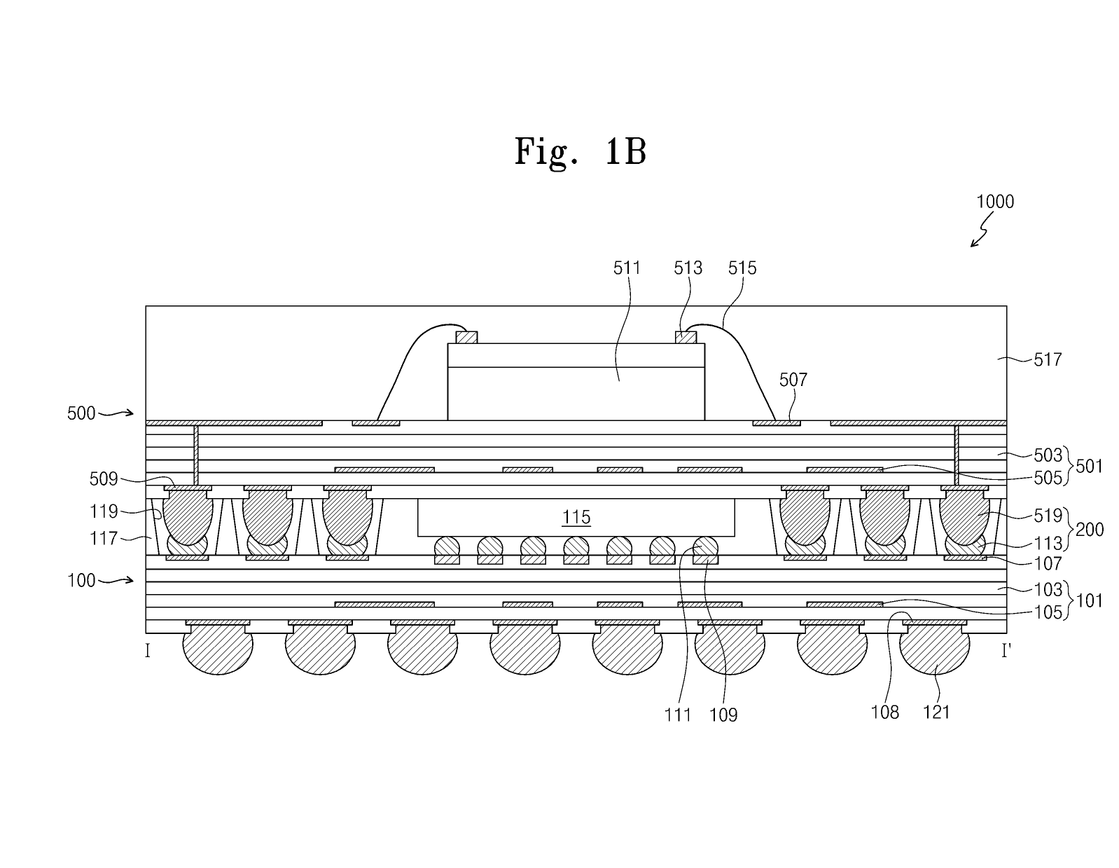

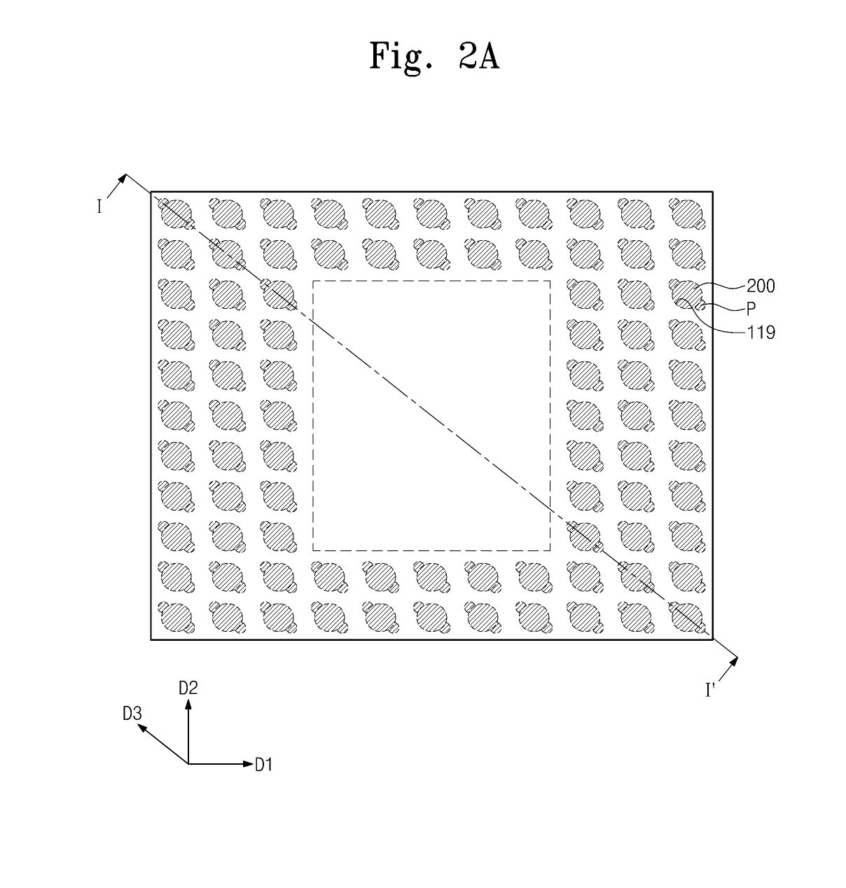

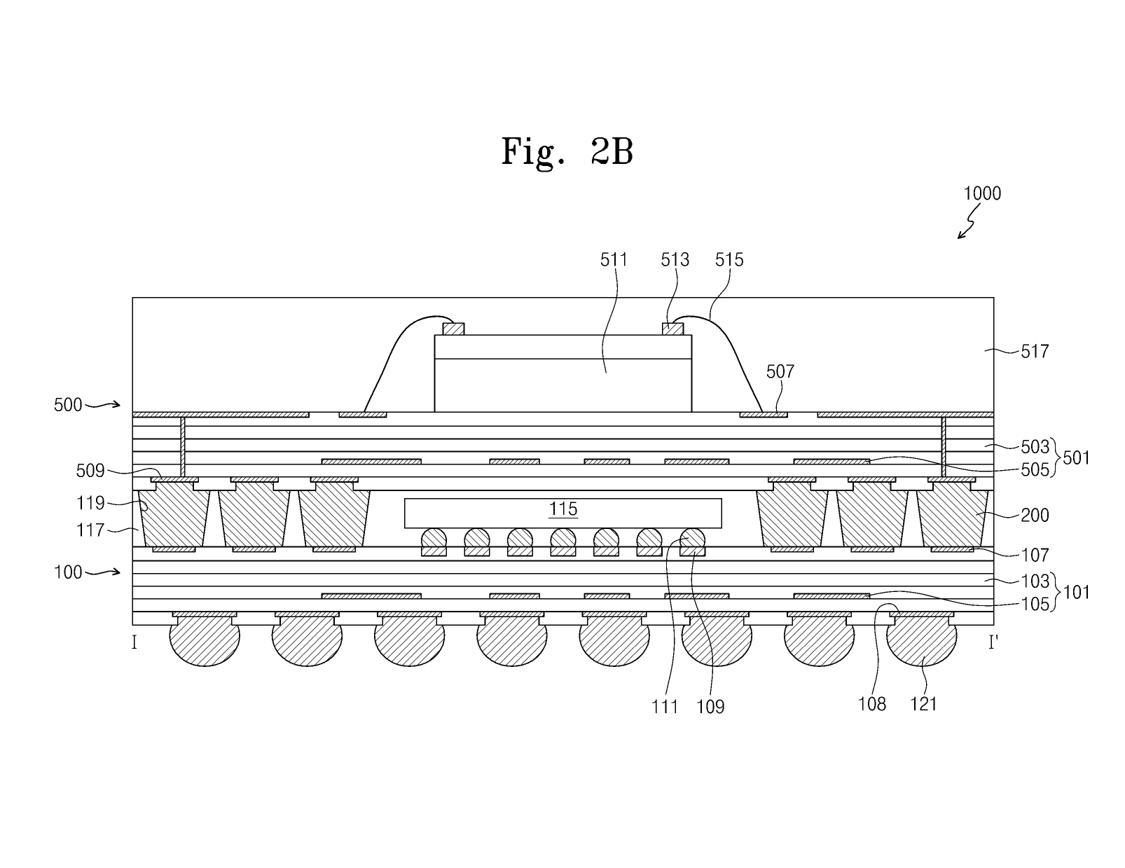

FIG. 1A is a plan view illustrating a semiconductor package according to an embodiment. FIG. 1B is a cross-sectional view taken along a line I-I′ of FIG. 1A. FIG. 2A is a plan view illustrating a semiconductor package according to another embodiment, and FIG. 2B is a cross-sectional view taken along a line I-I′ of FIG. 2A.

Referring to FIGS. 1A and 1B, a semiconductor package 1000 includes a lower package 100 and an upper package 500 stacked on the lower package 100.

The lower package 100 may include a lower package substrate 101, a lower semiconductor chip 115 disposed on the lower package substrate 101, chip bumps 111 electrically connecting the lower package substrate 101 to the lower semiconductor chip 115, and a lower molding layer 117 disposed on the lower package substrate 101 to substantially cover the lower semiconductor chip 115. In this embodiment, the lower molding layer 117 may leave a surface of the lower semiconductor chip 115 exposed. However, in other embodiments, the lower molding layer 117 may cover all exposed surfaces of the semiconductor chip 115.

The lower package substrate 101 may be a printed circuit board (PCB) including multiple layers. The lower package substrate 101 may include multiple insulating layers 103. An inner interconnection 105 may be disposed between the insulating layers 103. Lower connection pads 107 may be disposed at a top surface of the lower package substrate 101. Chip pads 109 may also be disposed at a top surface of the lower package substrate 101. Here, the lower connection pads 107 are disposed towards an edge of the top surface of the lower package substrate 101 and the chip pads 109 are disposed towards a center of the top surface; however, in other embodiments, the lower connection pads 107 and the chip pads 109 may be disposed in other locations according to other corresponding structures. Ball lands 108 may be disposed at a bottom surface of the lower package substrate 101. External terminals 121 may be attached to the ball lands 108. The external terminals 121 may electrically connect the semiconductor package 1000 to an external device.

The lower semiconductor chip 115 may be disposed on the chip pads 109. The chip bumps 111 are attached to a bottom surface of the lower semiconductor chip 115. The chip bumps 111 may contact the chip pads 109 to electrically connect the lower semiconductor chip 115 to the lower semiconductor substrate 101. For example, the semiconductor chip 115 may be a logic device such as a processor, a memory device, or the like. Alternatively, one portion of the lower semiconductor chip 115 may be a memory device, and the other portion of the lower semiconductor chip 115 may be a logic device. In other embodiments, different functions may be performed by different portions of the lower semiconductor chip 115. The lower molding layer 117 may substantially, if not fully fill between each of the chip bumps 111.

The lower molding layer 117 may include through holes 119 exposing the lower connection pads 107. The through holes 119 may be disposed along a circumference of the lower package 100. The through holes 119 may be arranged in first and second directions D1 and D2, which may be substantially perpendicular to each other. Although substantially perpendicular has been given as an example, in other embodiments, the first and second directions D1 and D2 may be different from each other. The through holes 119 may have a spaced distance L1 of about 5 μm to about 100 μm therebetween. Each of the through holes 119 may include protrusions P protruding in a third direction D3 and disposed on opposite sides of the corresponding through hole 119. Each of the protrusions P may overlap a portion of the through hole 119. The through hole 119 may have a diameter in a third direction D3 greater than that in the first or second direction D1 or D2. The through hole 119 may have a sidewall having a tapered shape. For example, the through hole 119 may have an upper width greater than a width at a bottom surface.

The upper package 500 may include an upper package substrate 501, an upper semiconductor chip 511 disposed on a top surface of the upper package substrate 501, a bonding wire 515 connecting the upper package substrate 501 to the upper semiconductor chip 511, and an upper molding layer 517 covering the upper semiconductor chip 511 on the package substrate 501.

The upper package substrate 501 may be a PCB or other substrate on which semiconductor chips may be mounted. The upper package substrate 501 may include a plurality of insulating layers 503 and inner interconnections 505 disposed between the insulating layers 503, like the lower package substrate 101. A wire pad 507 connected to the bonding wire 515 may be disposed at the upper surface of the upper package substrate 501. The upper connection pads 509 may be disposed at a bottom surface of the upper package substrate 501. The upper connection pads 509 may face corresponding lower connection pads 107.

The upper package chip 511 may be disposed on the upper package substrate 501. For example, the upper package chip 511 may be a logic device such as a processor, a memory device, or the like. Alternatively, one portion of the upper semiconductor chip 511 may be a memory device, and the other portion of the upper semiconductor chip 511 may be a logic device. In other embodiments, different functions may be performed by different portions of the upper semiconductor chip 511. A bonding pad 513 may be disposed on the upper semiconductor chip 511. The bonding pad 513 may be connected to the wire pad 507 through the bonding wire 515. Thus, the upper semiconductor chip 511 may be electrically connected to the upper package substrate 501.

Electrical connections 200 may be respectively disposed within the through holes 119 to electrically connect the lower package 100 to the upper package 500. Each of the electrical connections 200 may include lower and upper connections 113 and 519. The lower connection 113 may be attached to the lower connection pad 107, and the upper connection 519 may be attached to the upper connection pad 509. The electrical connection 200 may be expanded into the through hole 119 while the lower and upper connections 113 and 519 reflow when the upper package 500 is stacked on the lower package 100. A portion of the through hole 119 may be filled with the electrical connection 200. Thus, the sidewall of the through hole 119 may be spaced apart from the electrical connection 200. In a particular embodiment, the sidewall of the through hole 119 that is spaced apart from the electrical connection 200 may be disposed in the protrusions P of the through hole 119.

According to another embodiment, as illustrated in FIGS. 2A and 2B, the electrical connection 200 may be fully filled into the through hole 119. Thus, the sidewall of the through hole 119 may contact the electrical connection 200.

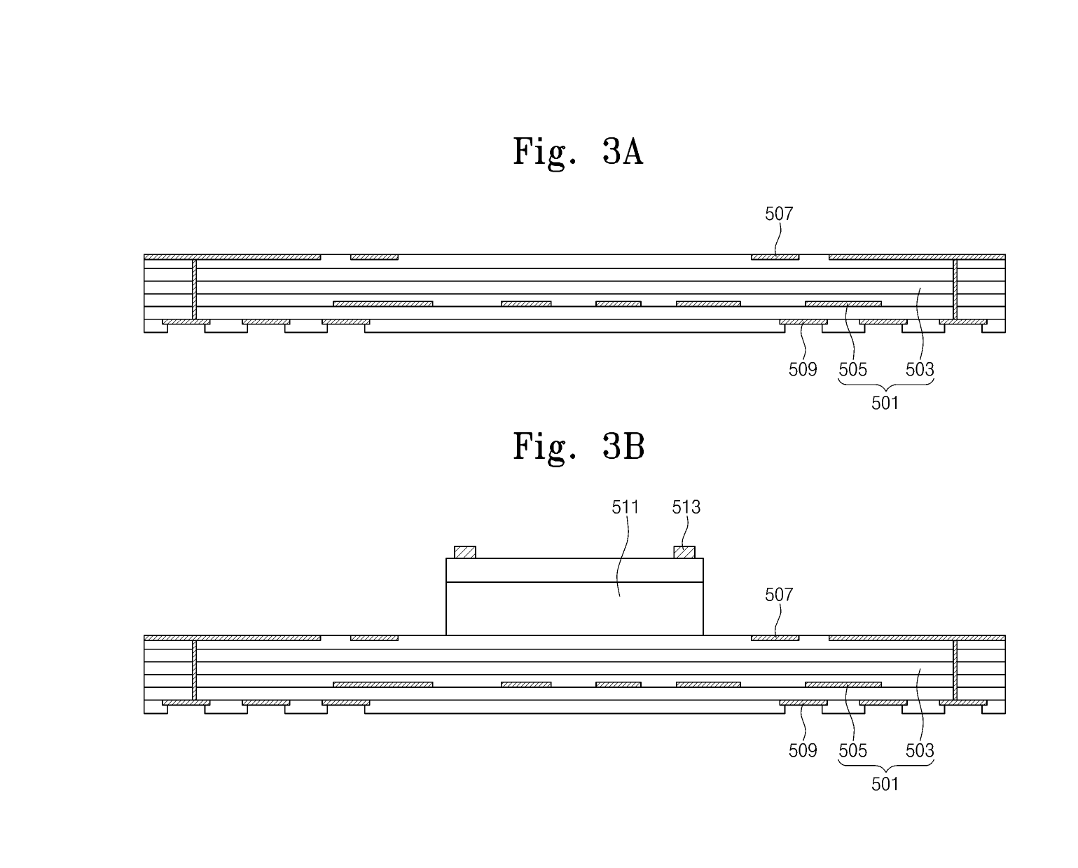

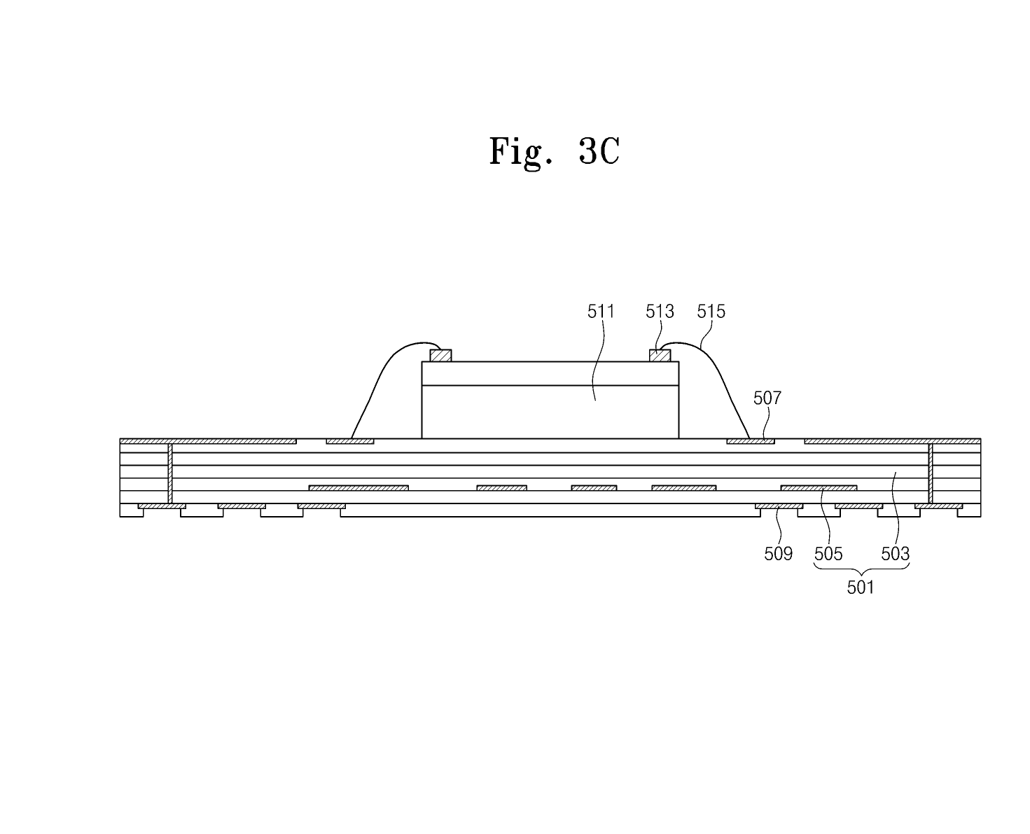

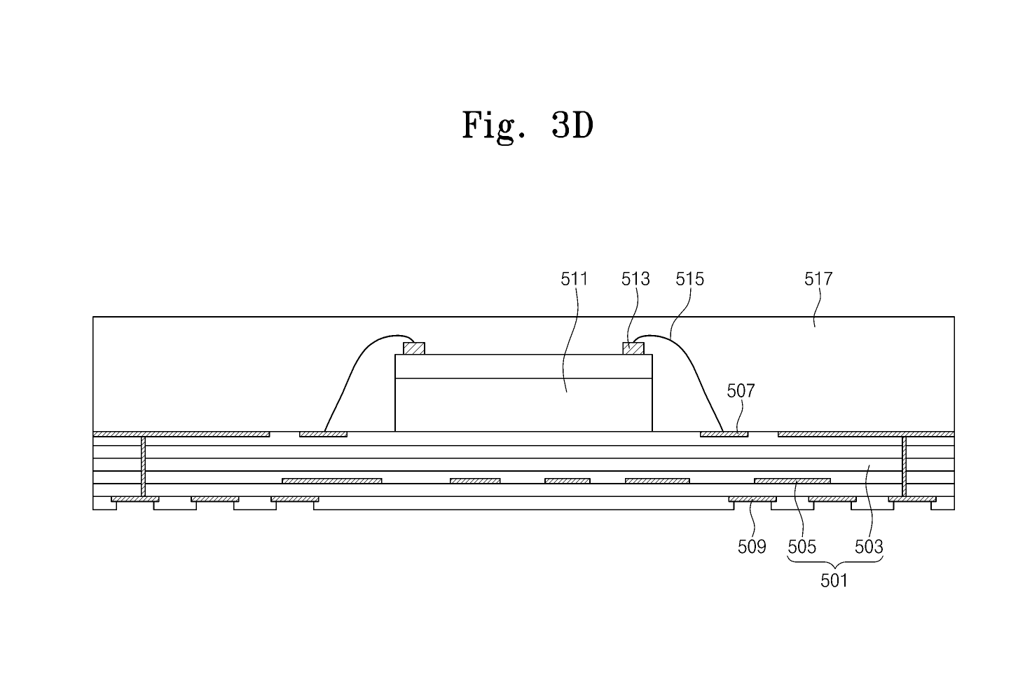

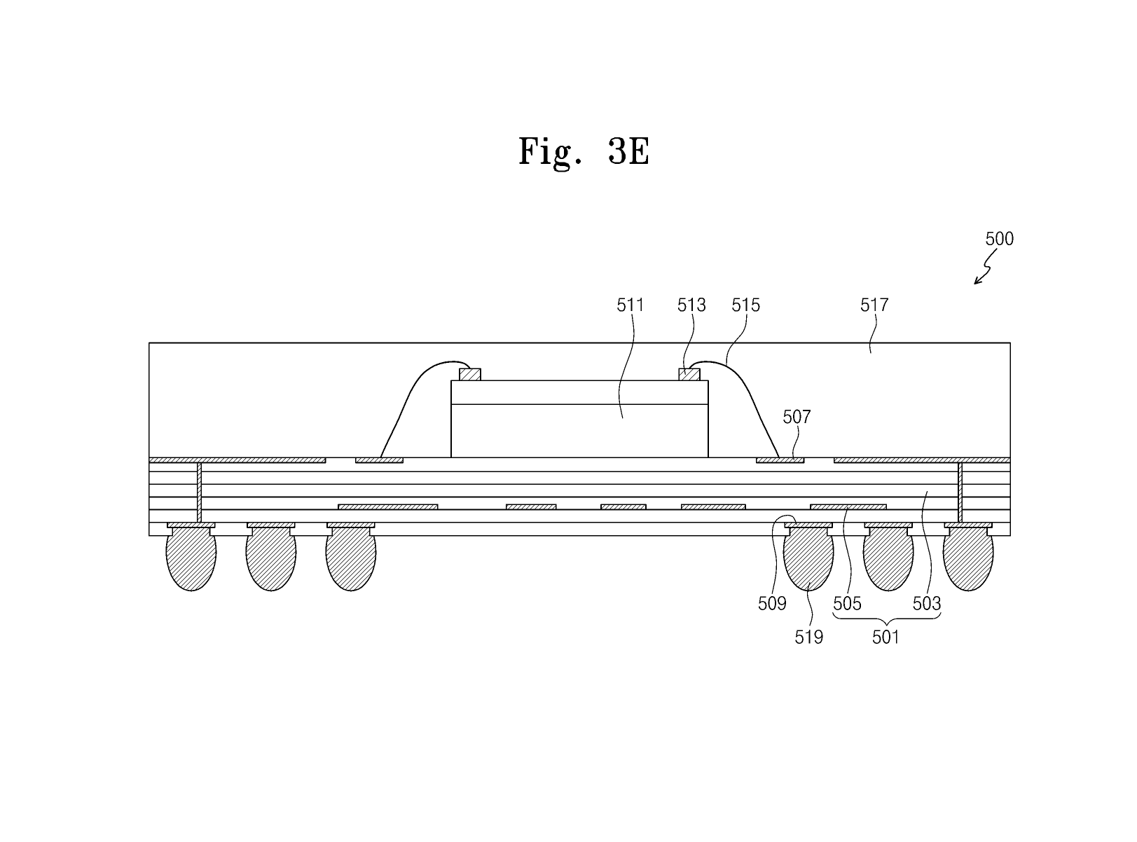

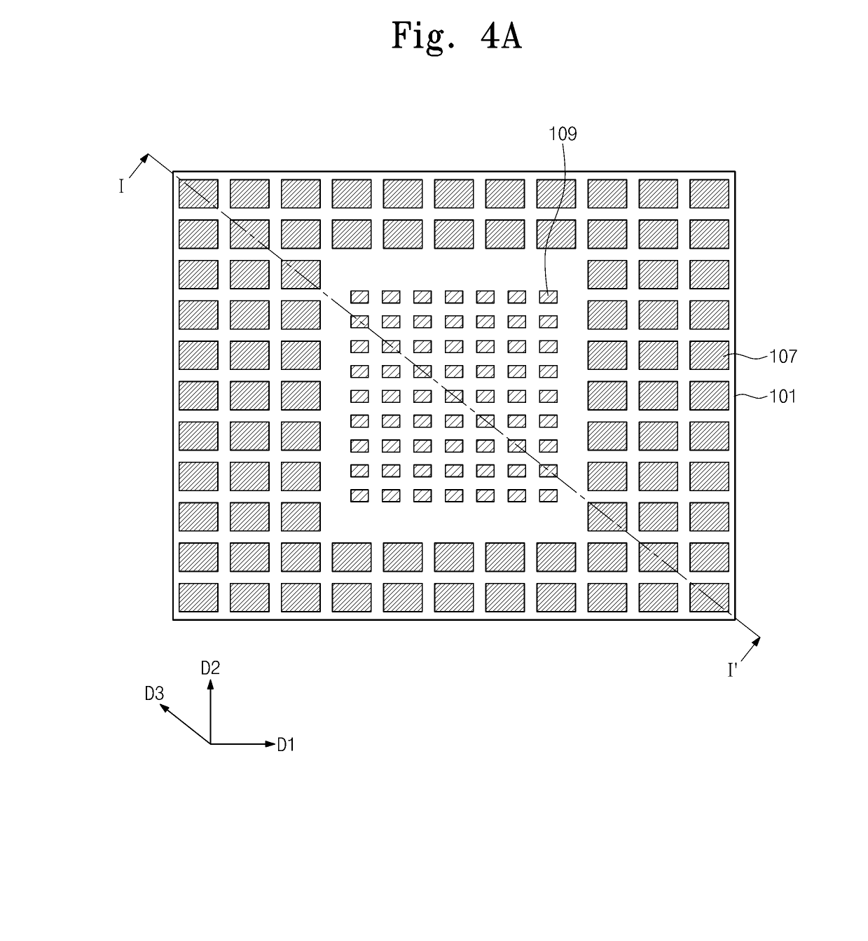

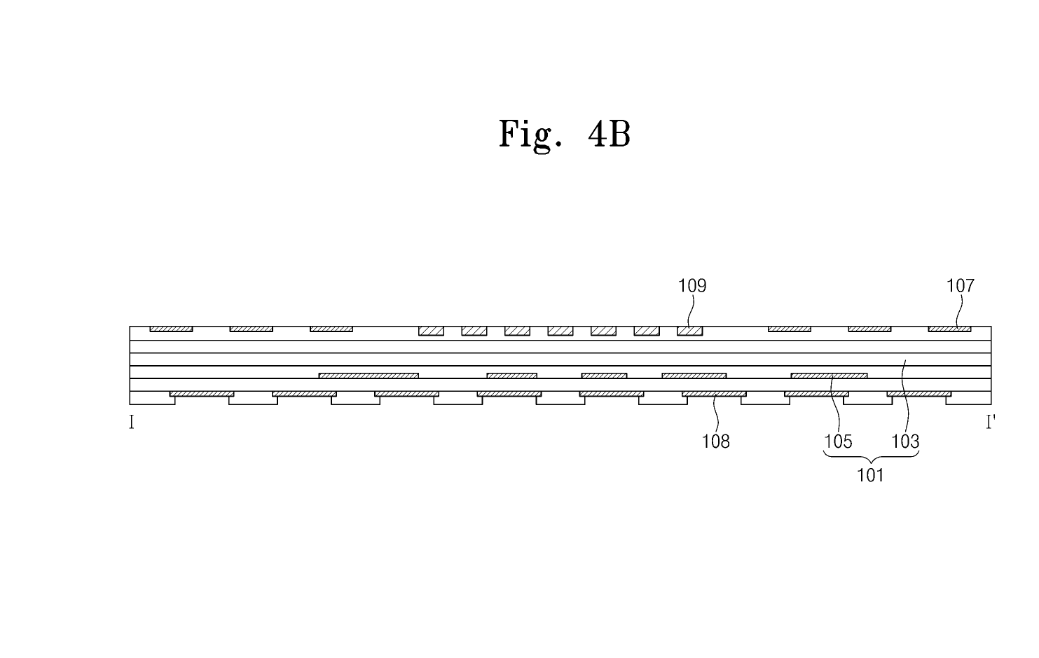

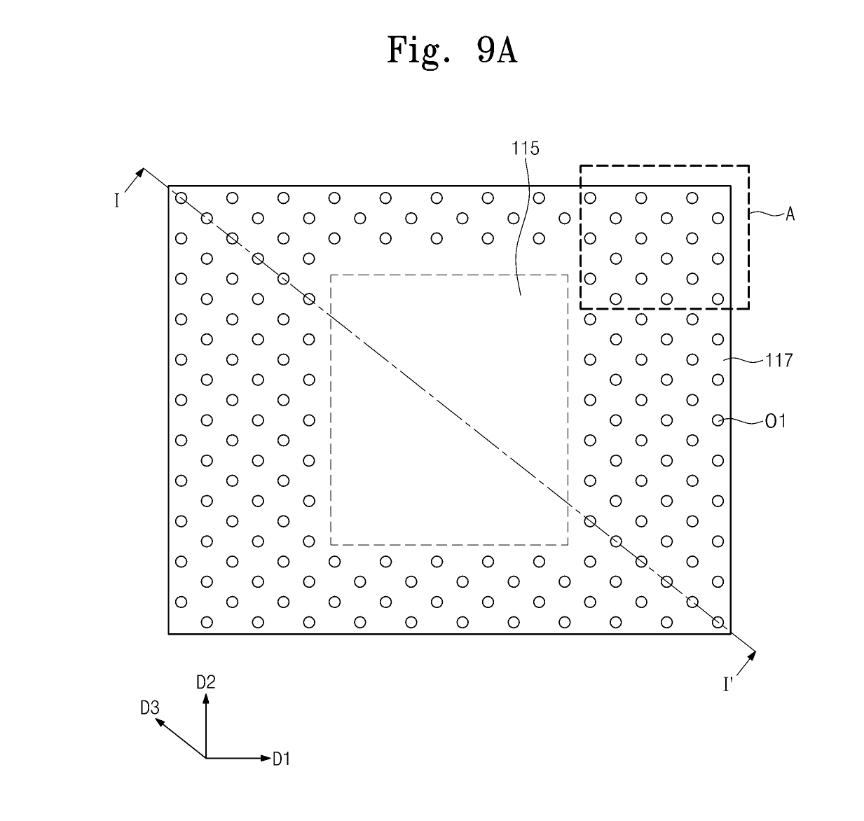

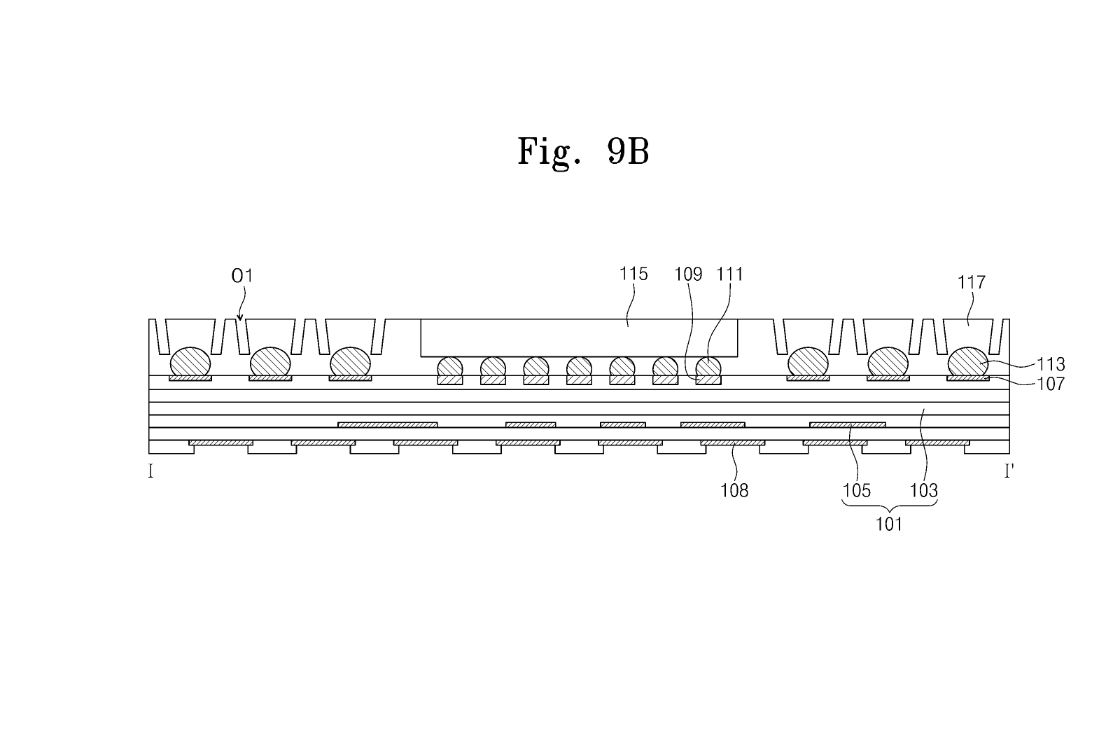

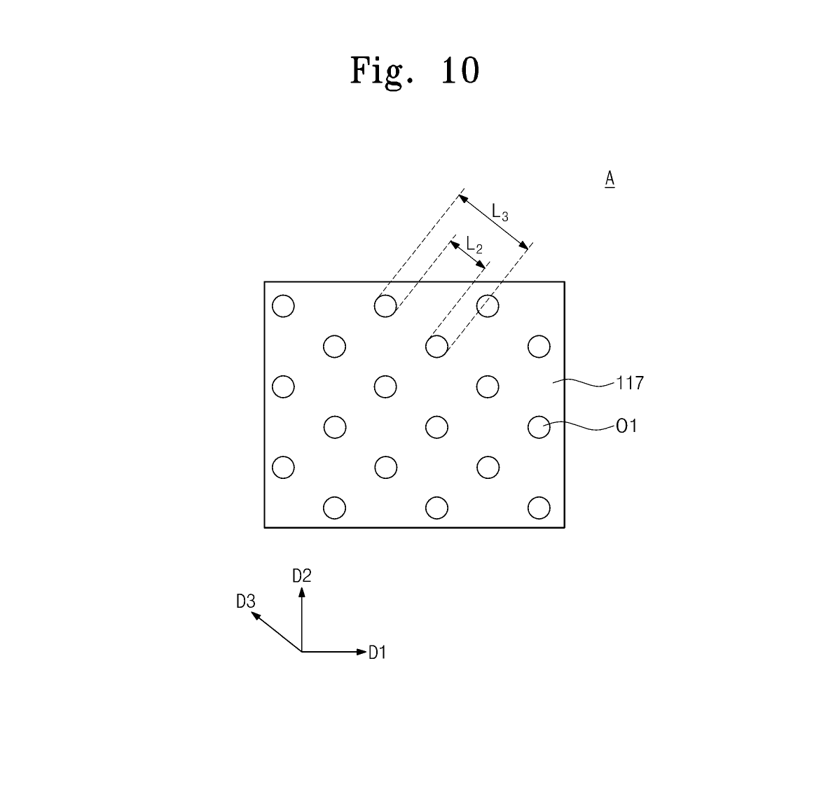

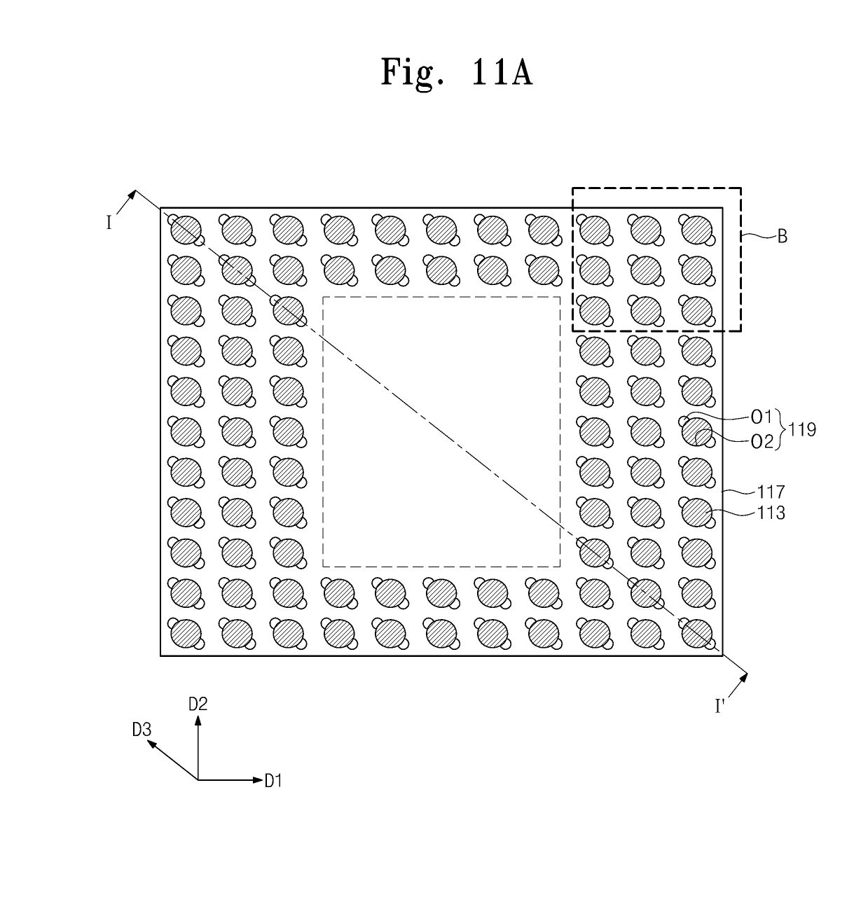

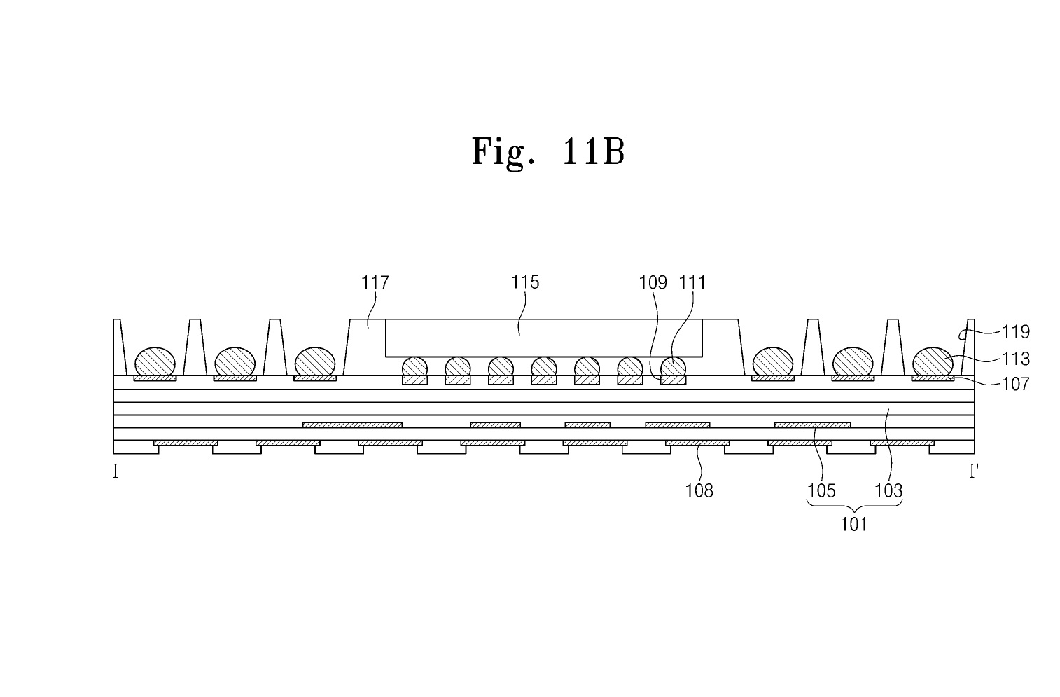

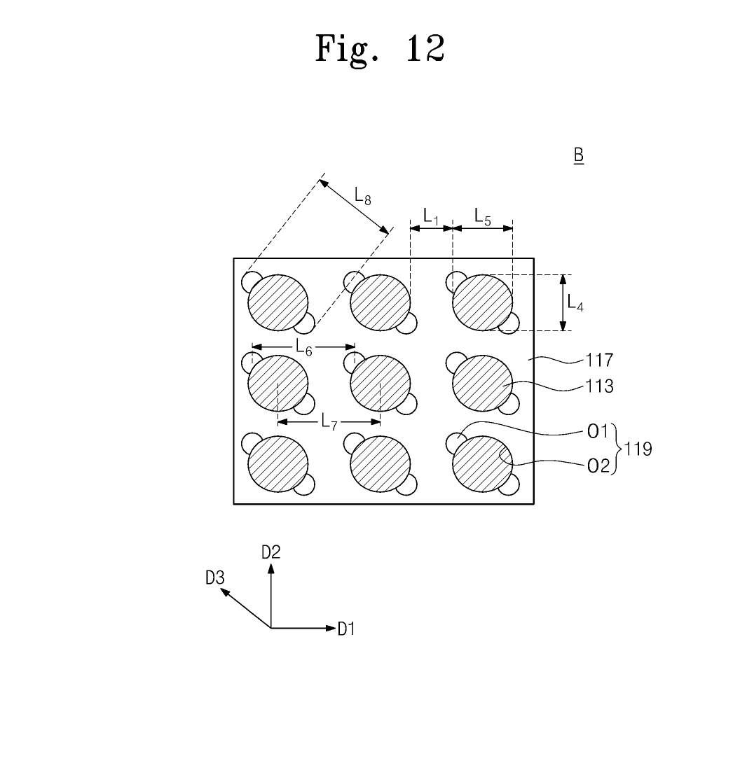

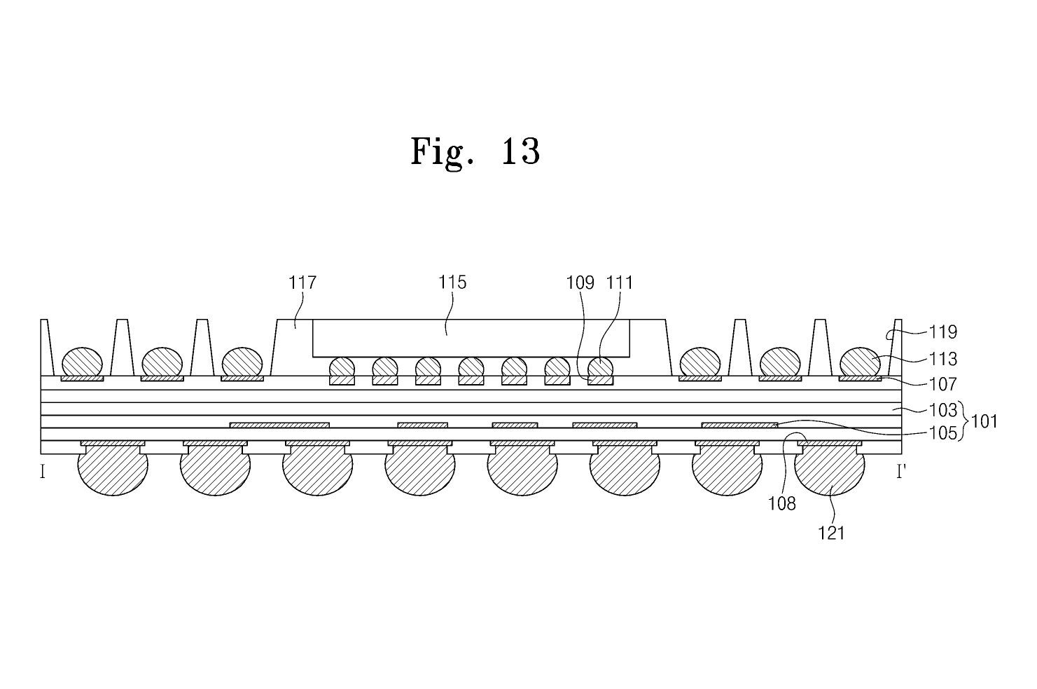

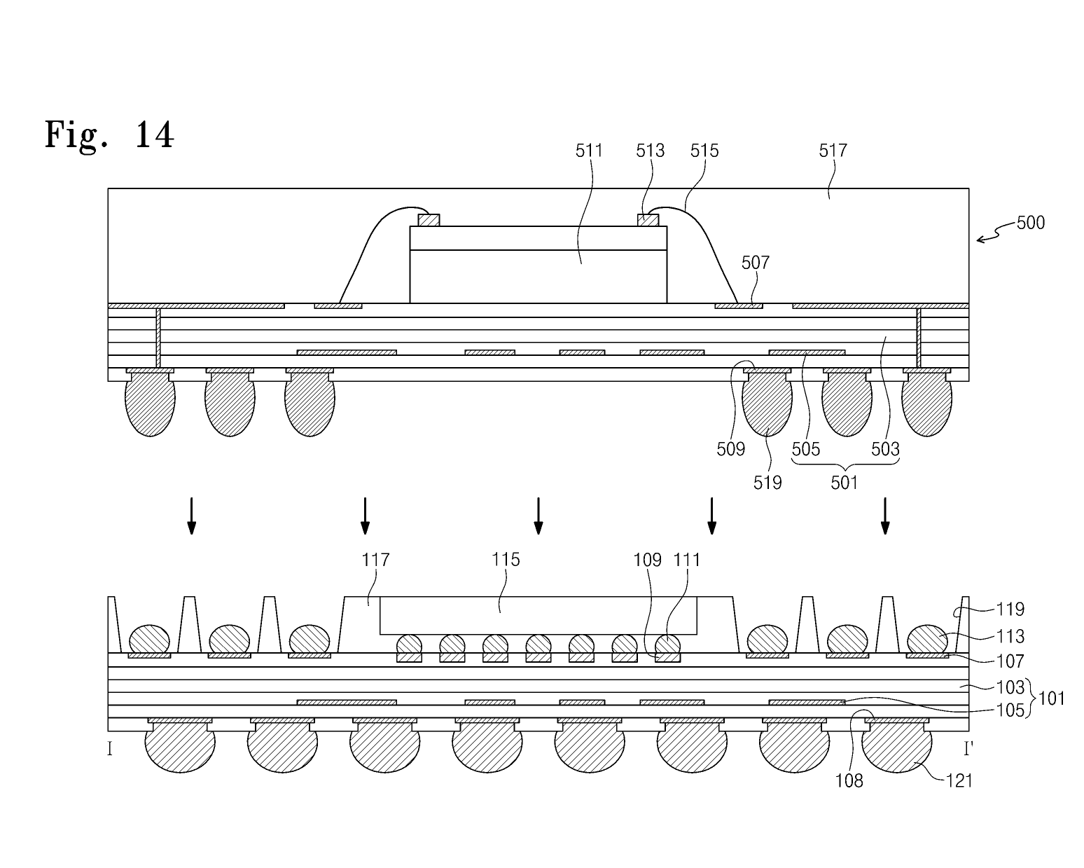

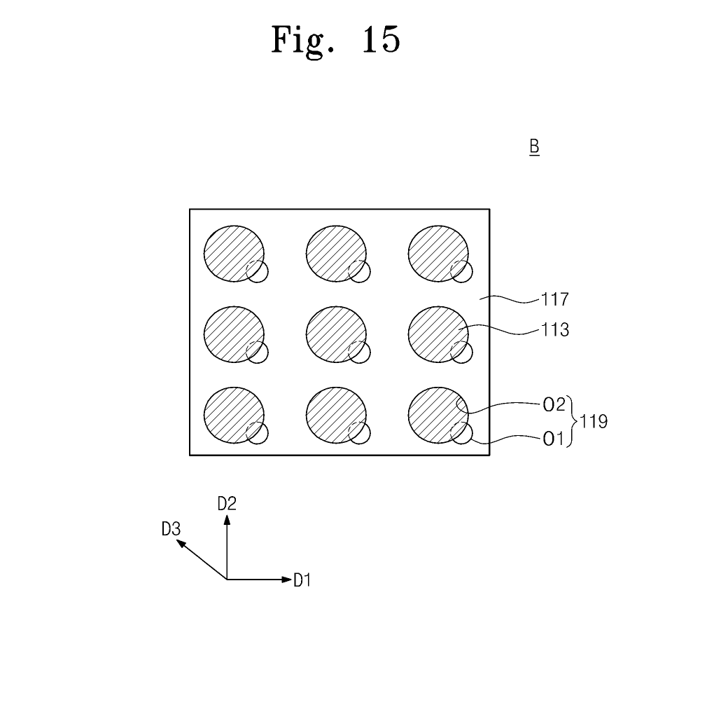

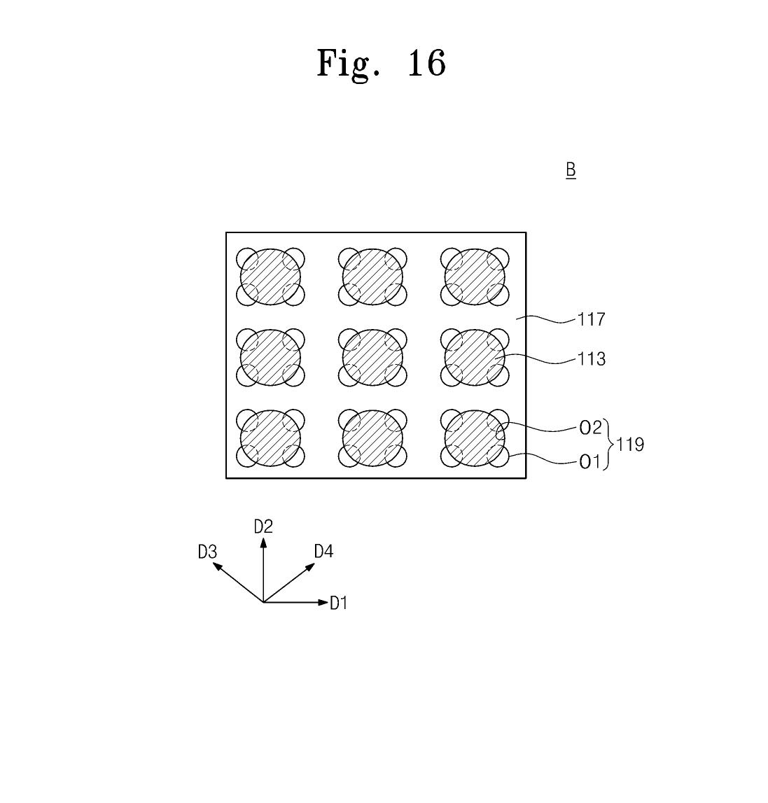

FIGS. 3A to 3E are cross-sectional views illustrating a method of fabricating an upper package according to an embodiment. FIGS. 4A to 9A and 11A are plan views illustrating a method of fabricating a lower package according to an embodiment. FIGS. 4B to 9B and 11B are cross-sectional views illustrating the method of fabricating the lower package according to an embodiment, taken along line I-I′ of FIGS. 4A to 9A and 11A. FIG. 10 is an enlarged plan view of a section A of FIG. 9A, which illustrates the method of fabricating the lower package according to an embodiment. FIG. 12 is an enlarged plan view of a section B of FIG. 11A, which illustrates the method of fabricating the lower package according to an embodiment. FIGS. 13 and 14 are cross-sectional views illustrating the method of fabricating the lower package according to an embodiment. FIG. 15 is an enlarged plan view of the section B of FIG. 11A, which illustrates a method of fabricating a lower package according to another embodiment. FIG. 16 is an enlarged plan view of the section B of FIG. 11A, which illustrates a method of fabricating a lower package according to further another embodiment.

Referring to FIG. 3A, an upper package substrate 501 may be prepared. The upper package substrate 501 may be a PCB or other substrate suitable for mounting semiconductor chips. The upper package substrate 501 may include a plurality of insulating layers 503. Inner interconnections 505 may be formed between the insulating layers 503. A wire pad 507 may be formed at an upper surface of the upper package substrate 501. Upper connection pads 509 may be formed at a bottom surface of the upper package substrate 501. The upper connection pads 509 may be exposed at the bottom surface of the upper package substrate 501.

Referring to FIG. 3B, an upper semiconductor chip 511 may be mounted on the top surface of the upper package substrate 501. The upper semiconductor chip 511 may be mounted on the upper package substrate 501 by an insulative adhesive (not shown) disposed between the upper semiconductor chip 511 and the upper package substrate 501. For example, the upper semiconductor chip 511 may be a logic device such as a processor, a memory device, or the like. Alternatively, one portion of the upper semiconductor chip 511 may be a memory device, and the other portion of the upper semiconductor chip 511 may be a logic device. In other embodiments, different functions may be performed by different portions of the upper semiconductor chip 511. The upper semiconductor chip 511 may include a bonding pad 513 formed at a top surface of the upper semiconductor chip 511.

Referring to FIG. 3C, the bonding pad 513 may be connected to the wire pad 507 through a bonding wire 515. Thus, the upper package substrate 501 may be electrically connected to the upper semiconductor chip 511.

Referring to FIG. 3D, an upper molding layer 517 may be formed on the upper package substrate 501. The upper molding layer 517 may fully cover the top surface of the upper package substrate 501 and the upper semiconductor chip 511. As a result, the upper semiconductor chip 511 may be additionally fixed to the upper package substrate 501 by the upper molding layer 517. The upper molding layer 517 may include an epoxy-based resin, polyimide, or the like.

Referring to FIG. 3E, upper connections 519 may be respectively attached to the upper connection pads 509. Thus, an upper semiconductor package 500 may be formed.

Referring to FIGS. 4A and 4B, a lower package substrate 101 may be prepared. The lower package substrate 101 may be a PCB or other suitable substrate for mounting semiconductor chips. The lower package substrate 101 may include a plurality of insulating layers 103 and inner interconnections 105, like the upper package substrate 501. Lower connection pads 107 may be formed at a top surface of an edge of the lower package substrate 101. Chip pads 109 may be formed at a top surface of a central portion of the lower package substrate 101 surrounded by the lower connection pads 107. However, as described above, the lower connection pads 107 and chip pads 109 may be formed at other locations at the top surface of the lower package substrate 101. The lower connection pads 107 and the chip pads 109 may be formed by depositing patterning, or plating a conductive material such as aluminum, copper, gold, silver, and platinum, an alloy thereof, or the like. In addition, ball lands 108 may be formed at a bottom surface of the lower package substrate 101. The ball lands 108 may be exposed at the bottom surface of the lower package substrate 101.

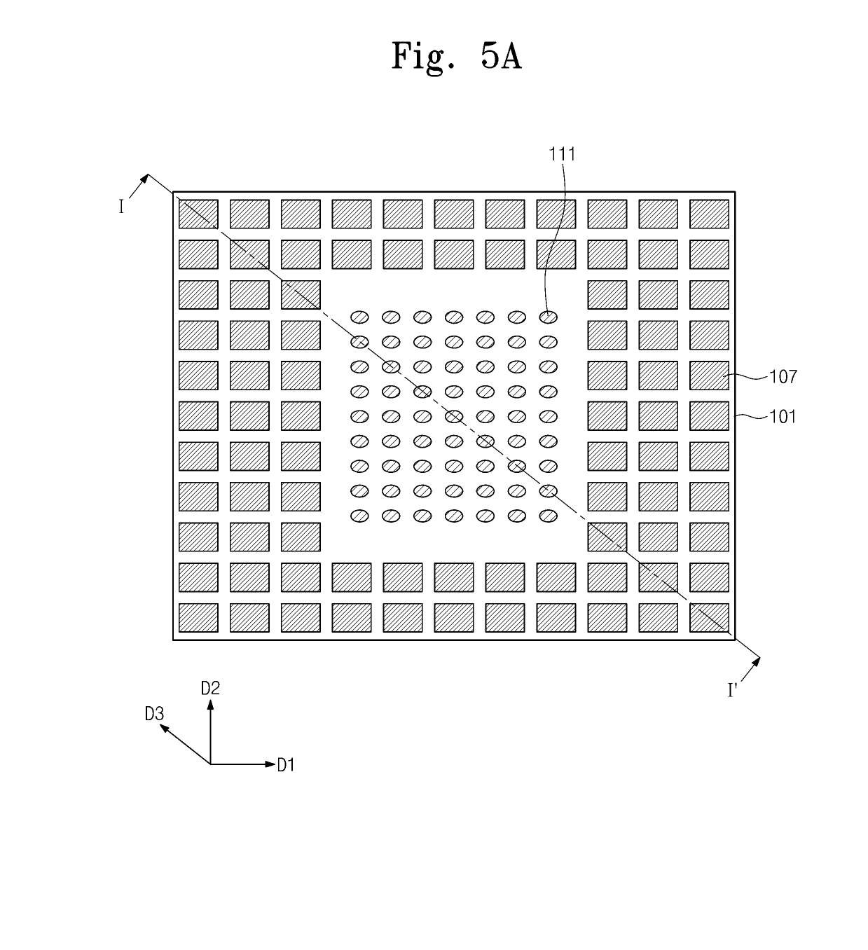

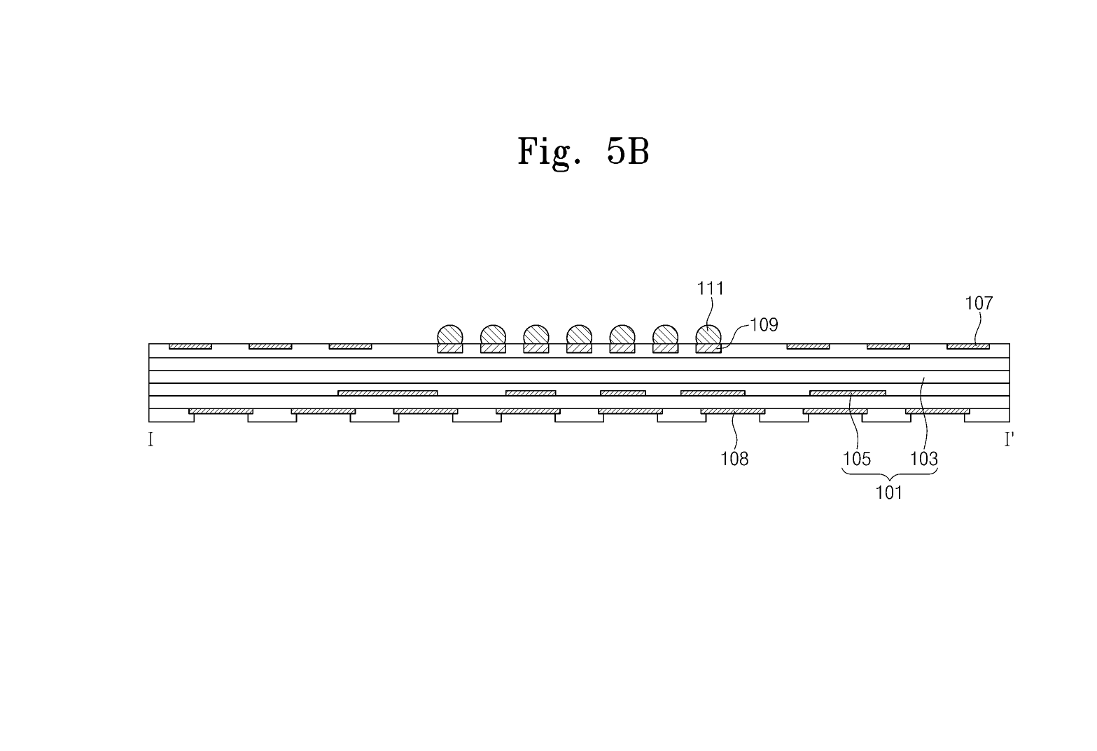

Referring to FIGS. 5A and 5B, chip bumps 111 may be respectively formed on the chip pads 109. The chip bumps 111 may be formed by using screen print technology, inkjet technology, soldering technology, or the like. Each of the chip bumps 111 may include a conductive material such as a metal. The chip bumps 111 may be electrically connected to the chip pads 109, respectively.

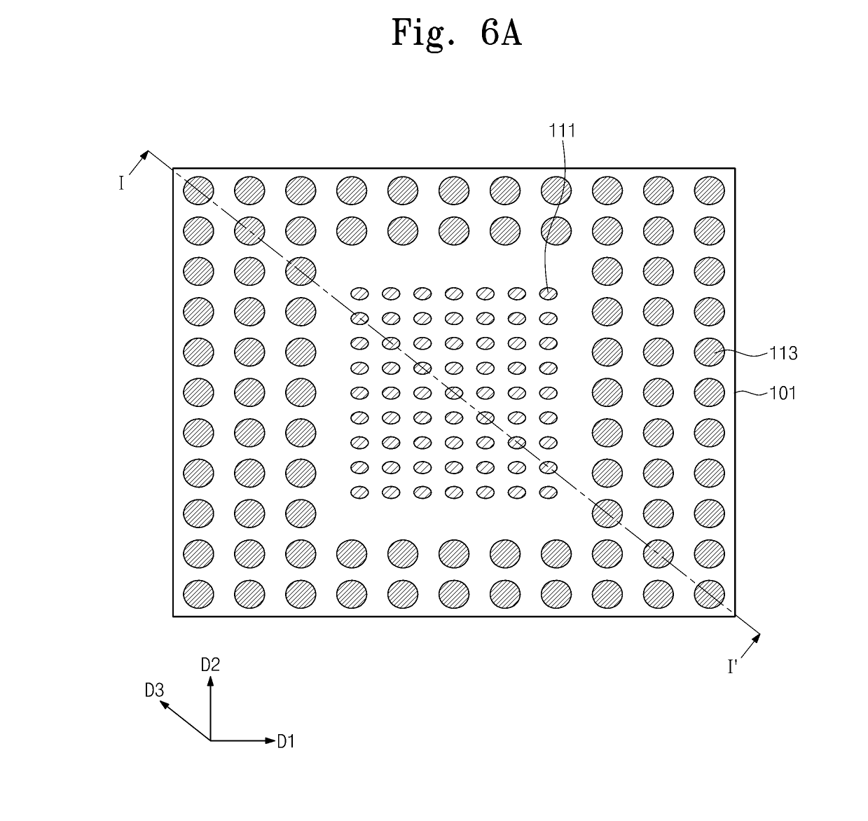

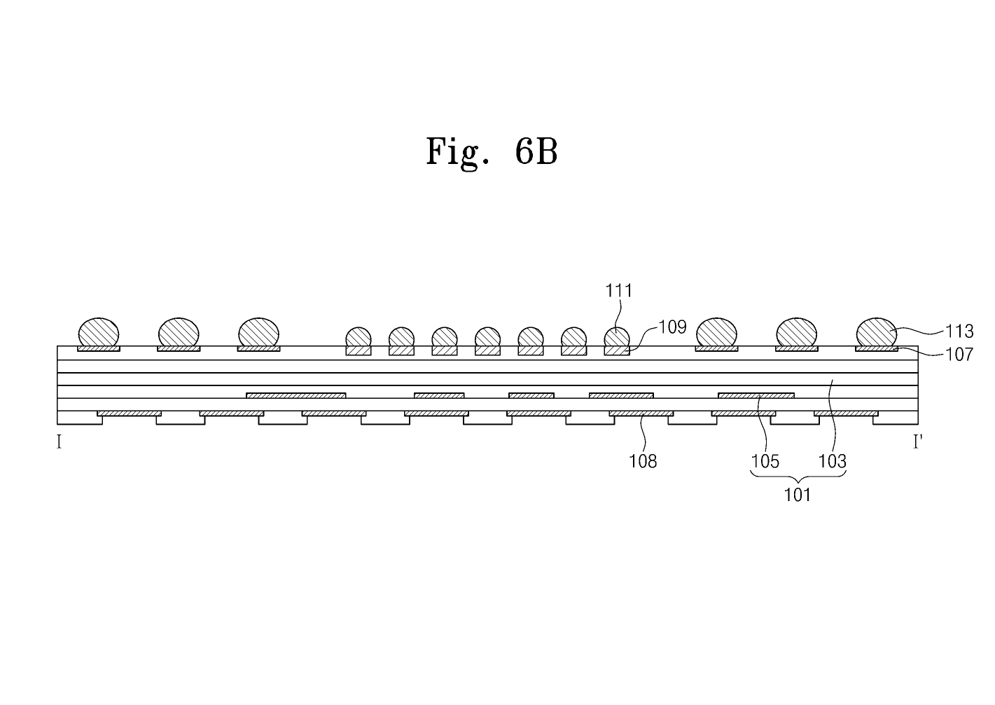

Referring to FIGS. 6A and 6B, lower connections 113 may be respectively formed on the lower connection pads 107. The lower connections 113 may be formed by using screen print technology, inkjet technology, soldering technology, or the like. Although the lower connections 113 may be formed using the same technology as the chip bumps 111, in other embodiments, the lower connections 113 and chip bumps 111 may be formed using different technologies. Each of the lower connection pads 107 may include a conductive material such as a metal. The lower connections 113 and the chip bumps 111 may be formed at the same time. Although the lower connections 113 and the chip bumps 111 are illustrated as being different in size, in other embodiments, each of the lower connections 113 may have the same size as each of the chip bumps 111.

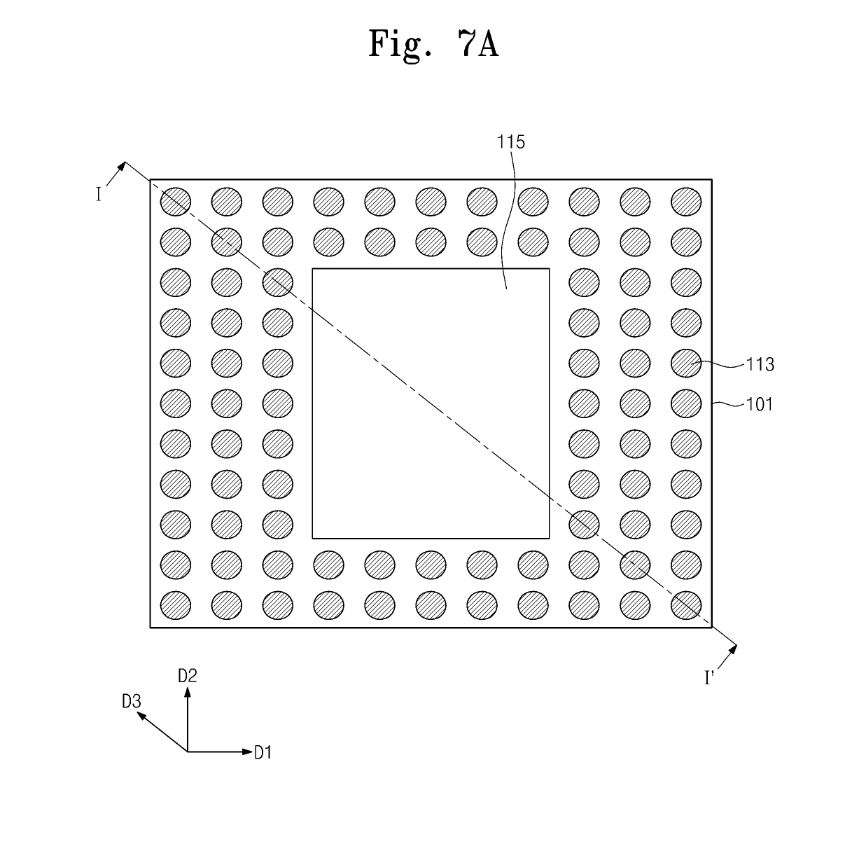

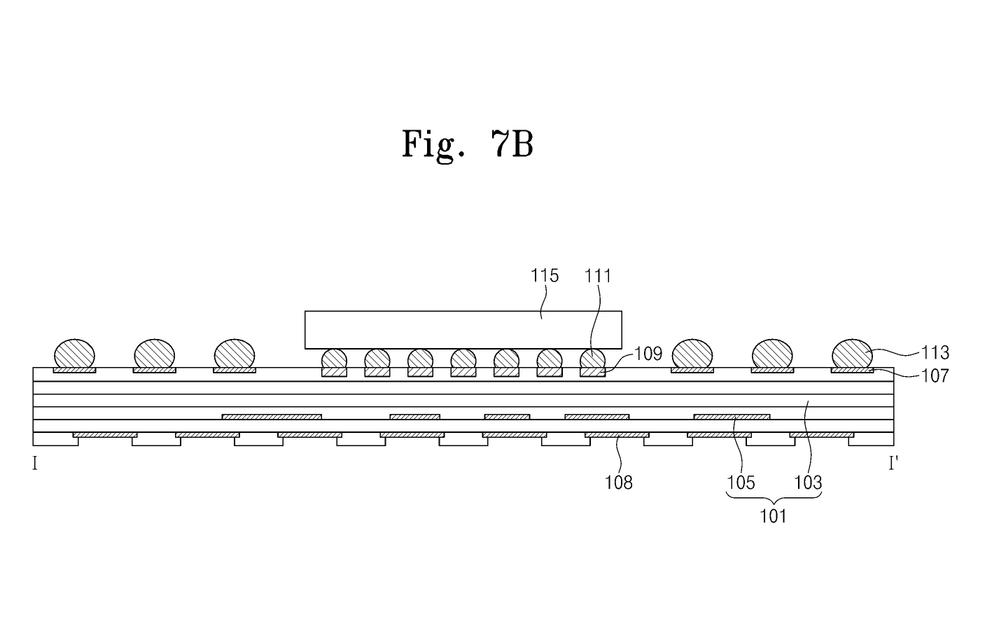

Referring to FIGS. 7A and 7B, a lower semiconductor chip 115 may be mounted on the chip bumps 111. As a result, the lower semiconductor chip 115 may be attached to the chip bumps 111. Alternatively, the chip bumps 111 may be formed at a bottom surface of the lower semiconductor chip 115 instead of or in addition to being formed at the chip pads 109 as described above. The chip bumps 111 formed on the lower semiconductor chip 115 may adhere to the chip pads 109 by using a flip chip bonding method. Thus, the lower semiconductor chip 115 may be electrically connected to the lower package substrate 101 through the chip bumps 111. The lower semiconductor chip 115 may be substantially surrounded by the lower connections 113. The lower semiconductor chip 115 may be a logic device such as a processor, a memory device, or the like. Alternatively, one portion of the lower semiconductor chip 115 may be a memory device, and the other portion of the lower semiconductor chip 115 may be a logic device. In other embodiments, different functions may be performed by different portions of the lower semiconductor chip 115. Although not shown, the lower semiconductor chip 115, for example, may include a plurality of semiconductor chips that are stacked on each other. The semiconductor chips may be vertically aligned or misaligned. An insulative material layer may be disposed between the semiconductor chips.

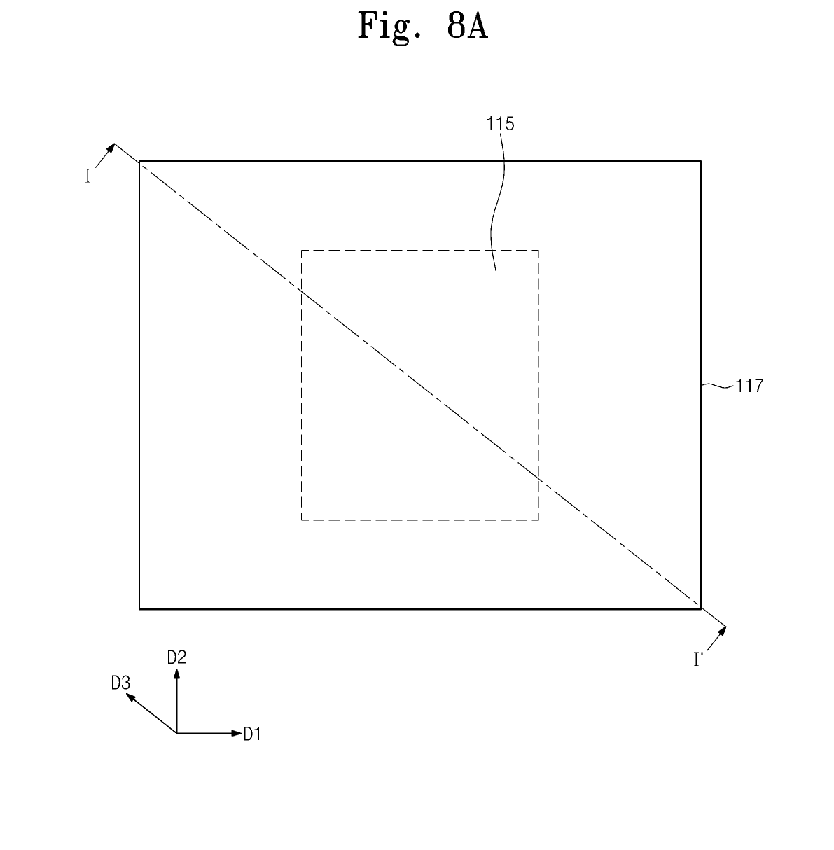

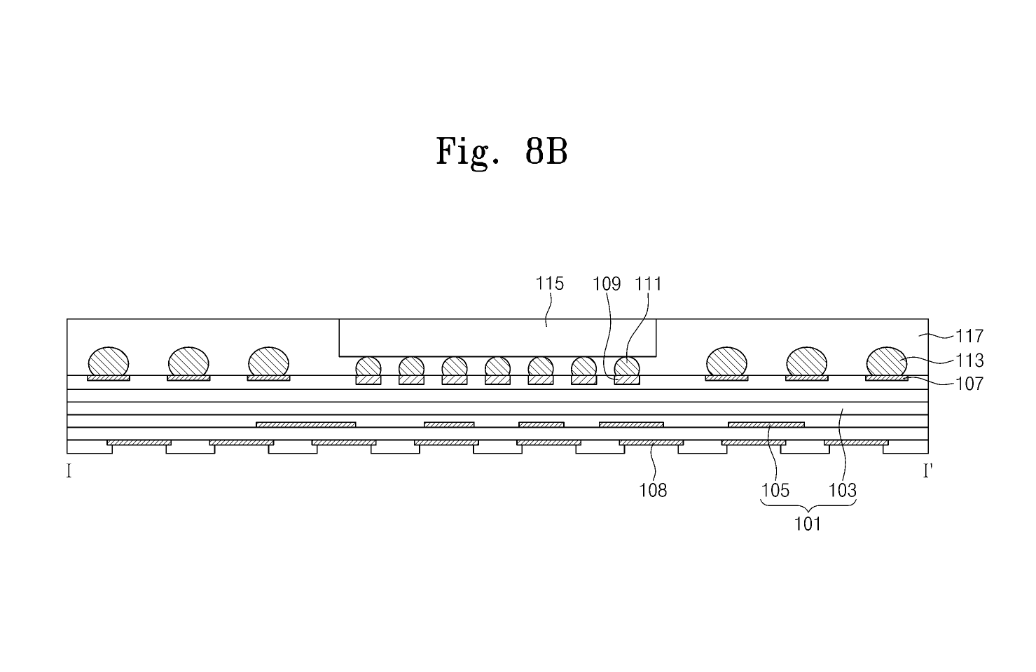

Referring to FIGS. 8A and 8B, a lower molding layer 117 may be formed on the lower package substrate 101. The lower molding layer 117 may be filled between the chip bumps 111 to cover the lower connections 113 and substantially surround the lower semiconductor chip 115. For example, the lower molding layer 117 may be formed by a molded underfill (MUF) method. A grinding process may be performed on a top surface of the lower molding layer 117. As a result, the top surface of the lower package substrate 101 may be exposed when the grinding process is performed. The lower molding layer 117 may include an epoxy molding compound, an epoxy-based resin, polyimide, or the like.

Referring to FIGS. 9A, 9B, and 10, a first laser drilling process is performed on the lower molding layer 117. First openings O1 may be formed in portions of the lower molding layer 117 by the first laser drilling process. The first laser drilling process may be performed so that the lower connections 113 buried in the lower molding layer 117 are not damaged. For example, the first openings O1 may be formed so that the lower connections 113 are not exposed. Each of the first openings O1 may have a sidewall having a tapered-shape. In other embodiments, the first openings O1 may be formed by laser drilling at an angle offset from an angle substantially perpendicular to a top surface of the lower molding layer 117. In some embodiments, for first openings O1 associated with a single lower connection 113, those first openings O1 are angled to extend towards the corresponding lower connection 113. In other words, those openings O1 may become less separated as the openings O1 extend into the lower molding layer 117.

Referring to FIG. 10 that is an enlarged view of a portion A of FIG. 9A, the shortest distance L2 between the first openings O1 facing each other in a third direction D3 may be equal to or less than each of diameters L4 and L5 of each of second openings O2 (see FIGS. 11A and 12) formed by a following process. Also, the longest distance L3 between the first openings O1 facing each other in the third direction D3 may be greater than each of the diameters L4 and L5 of the second opening O2 (see FIGS. 11A and 12).

Referring to FIGS. 11A, 11B, and 12, a second laser drilling process may be performed on the lower molding layer 117. The second laser drilling process may be performed on the lower molding layer 117 disposed between the first openings O1 facing each other in the third direction D3 to form the second openings O2 each substantially overlapping at least a portion of the corresponding first openings O1. The lower connections 113 buried in the lower molding layer 117 may be substantially, if not entirely exposed by the second openings O2. Referring to FIG. 12 that is an enlarged view of a portion B of FIG. 11A, the second openings O2 may have a distance L1 of about 5 μm to about 100 ƒm therebetween. According to an embodiment, a distance L6 between central portions of the first openings O1 in the first direction D1 may be the same as that L7 between central portions of the second openings O2 in the first direction D1. The first and second openings O1 and O2 may be defined as through holes 119. Thus, each of the through holes 119 may have protrusions (corresponding to the first openings O1) protruding from both sides thereof in the third direction D3. Each of the through holes 119 may have substantially the same diameter L4 and L5 in the first and second directions D1 and D2. Alternatively, the diameter L4 of the through hole 119 in the first direction D1 may be different from the diameter L5 of the through hole 119 in the second direction D2. In this case, the through hole 119 may have an oval shape. A diameter L8 of the through hole 119 in the third direction D3 may be greater than each of the diameters L4 and L5 of the through hole 119 in the first and second directions D1 and D2.

According to another embodiment, the first openings O1 may be formed to overlap a side surface of the second opening O2 in the third direction (D3) as shown in FIG. 15. Thus, each of the through holes 119 may have a convex protrusion (corresponding to the openings O1) in a side surface thereof in the third direction D3.

According to further another embodiment, the first openings O1 may overlap both side surfaces of the second opening O2 in the third direction D3 and in the fourth direction D4 substantially perpendicular to the third direction D3 as shown in FIG. 16. That is, the through hole 119 may include one second opening O2 and four first openings O1. Thus, the through hole 119 may have four protrusions (corresponding to the first openings O1).

Although not shown, the first openings O1 may be overlap opposite side surfaces of the second opening O2 in the third direction (D3) and one side surface of the second opening O2 in the fourth direction (D4) substantially perpendicular to the third direction (D3). That is, each of the through holes 119 may have one second opening O2 and three first openings O1. Although particular combinations of a second opening O2 and corresponding one or more first openings O1 have been described, in other embodiments, first openings O1 may be disposed at any position and in any number along the side surface of the second opening O2. Moreover, although first openings O1 having substantially the same size have been described, the first openings O1 along the side surface of a corresponding second opening O2 may have different sizes.

Referring to FIG. 13, external terminals 121 may be respectively formed on the ball lands 108. The external terminals 121 may be electrically connected to the chip bumps 111, respectively. The external terminals 121 may be formed by a soldering process. The external terminals 121 may be formed to form a lower package 100.

Referring to FIG. 14, at least one of the lower package 100 and the upper package 500 may approach one another to attach the lower and upper packages 100 and 500 to each other. For example, the upper package 500 may be stacked on the lower package 100. Thus, the upper connection 519 of the upper package 500 may be inserted into the through hole 119.

Referring again to FIGS. 1A and 1B, the reflowing process may be performed so as to expand the upper connection 519 into the through hole 119 and to couple the upper connection 519 to the lower connection 113. The upper connection 519 and the lower connection 113 may be melted and then coupled to each other to form the electrical connection 200. The electrical connection 200 may substantially fill the through holes 119. If the upper and lower connections 519 and 113 may have a total volume less than a volume of the through hole 119, the electrical connection 200 may be extend into only a portion of the through hole 119. Thus, the sidewall of the through hole 119 may be spaced apart from the electrical connection 200. Alternatively, referring to FIGS. 2A and 2B, if the upper and lower connections 519 and 113 have substantially the same total amount as a volume of the through hole 119, the electrical connection 200 may be substantially fully filled into the through hole 119. The lower and upper packages 100 and 500 physically coupled to each other by the connection 119 may be electrically connected to each other. Thus, the upper package 500 may be stacked on the lower package 100 to realize a semiconductor package 1000 having a PoP structure.

The number of the electrical connections may increase to improve electrical performance between the semiconductor packages. Thus, the volume of each of the through holes in which the electrical connections are formed may decrease. If the volume of the through hole decreases, the electrical connection that is formed by melting the lower and the upper connections may protrude outside from the through holes to contact other electrical connections adjacent thereto, thereby causing short circuit of the semiconductor package.

When the through holes are arranged in a longitudinal direction (that is, the first direction D1) and in a transversal direction (that is, the second direction D2) perpendicular to the longitudinal direction, a width between the through holes facing each other in a diagonal direction (that is, the third direction D3) with respect to the longitudinal and the transversal directions may be greater than that between the through holes facing each other in the longitudinal and transversal directions. The first laser drilling process may be performed to form the first openings O1 in the third direction D3 that is a diagonal direction of the second openings O2 before the second openings O2 are formed to use spaces between the through holes 119 adjacent to each other in the diagonal direction. Then, the second laser drilling process may be performed to form the second openings O2, which overlap the first openings O1, between the first openings O1. Thus, each of the through holes 119 having the first openings O1 may a larger volume when compared to the volume of each of the through holes 119 that do not have the first openings O1. Therefore, the through holes 119 having an expanded volume may prevent the electrical connection 200 from protruding outward therefrom to realize the semiconductor package 100 having improved reliability.

In an embodiment, the first openings O1 may be formed such that a minimum distance from the first opening to an adjacent second opening is a local maximum. That is, the first openings may be formed such that the first openings are the furthest from an adjacent through hole.

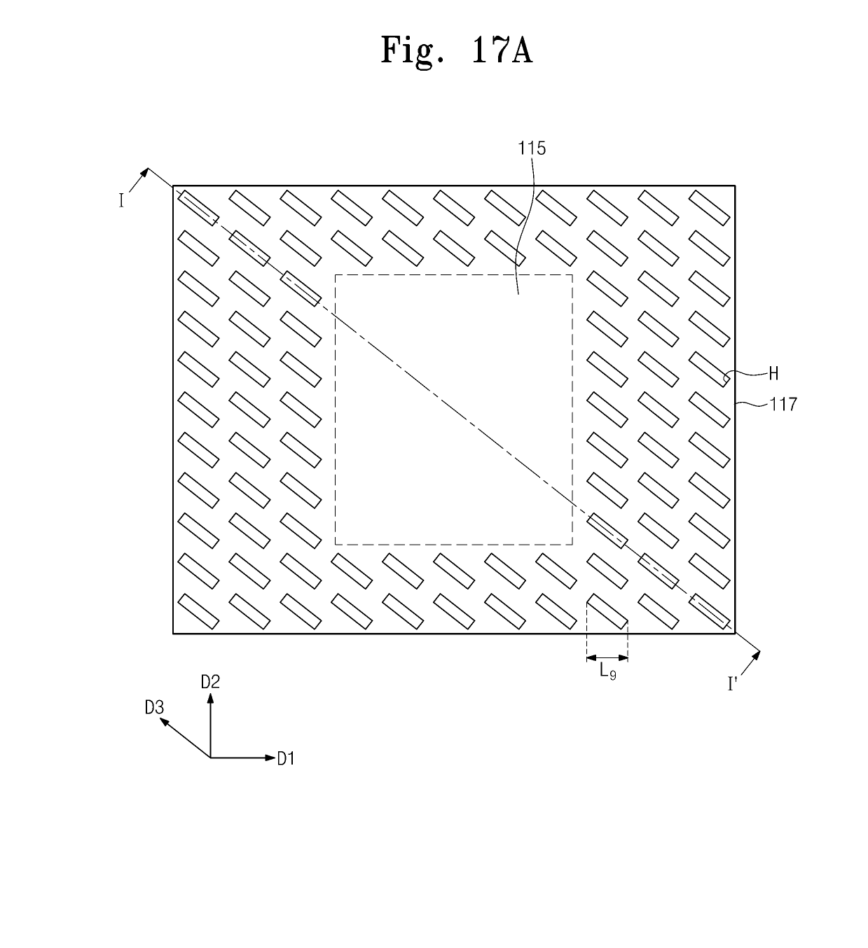

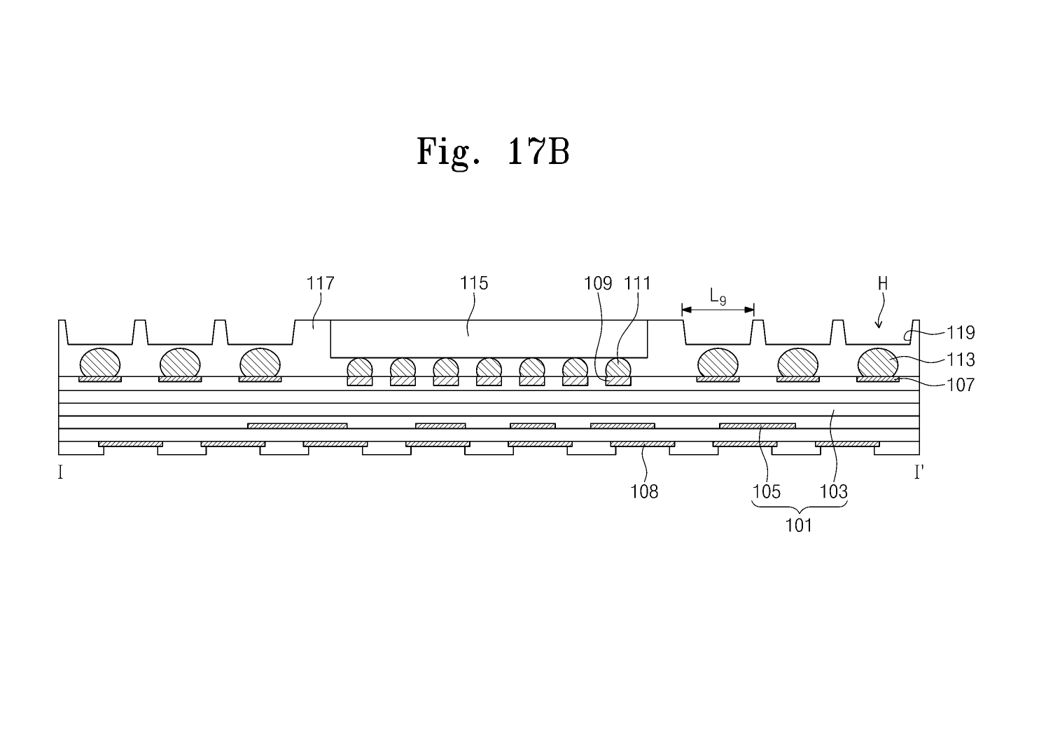

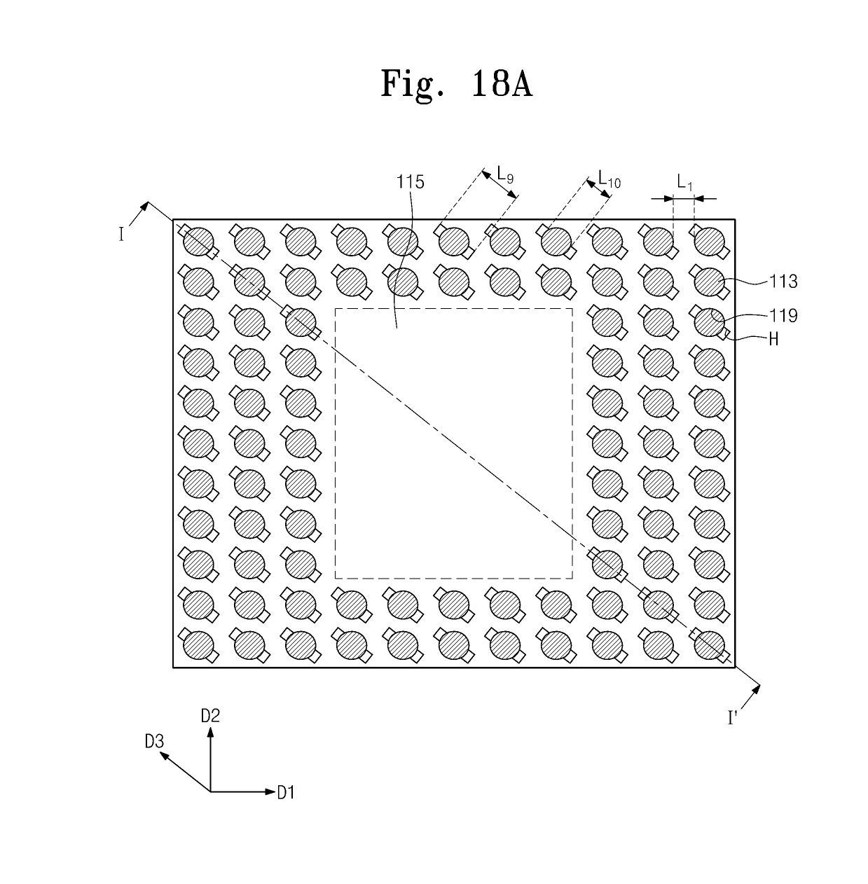

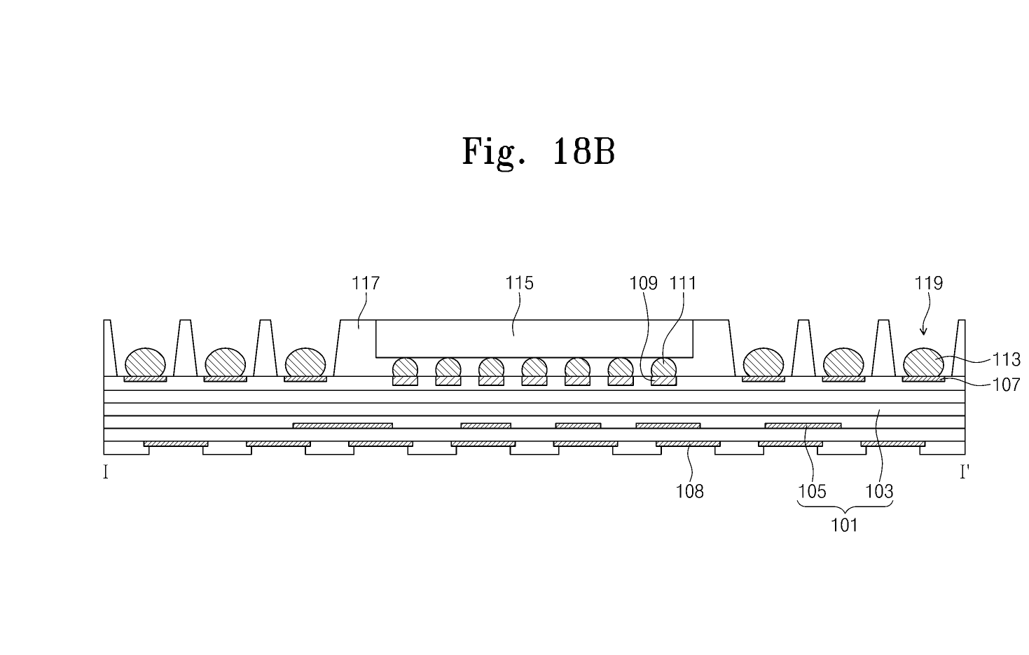

FIGS. 17A and 18A are cross-sectional views illustrating a method of fabricating a lower package according to another embodiment, and FIGS. 17B and 18B are cross-sectional views taken along line I-I′ of FIGS. 17A and 18A. For brief description, redundant technical and structural features and the fabricating method will be omitted with reference to FIGS. 4A to 11A and 4B to 14B.

Referring to FIGS. 17A and 17B, a first laser drilling process is performed on a lower molding layer 117 to form line openings H. The line openings H may be arranged at a uniformly spaced distance in the first and second directions D1 and D2. The line openings H may be formed such that a long axis of each of the line openings H extends along a third direction D3. A distance L9 of the long axis of the line opening H may be greater than a diameter of each of through holes 119 formed by a following process.

Referring to FIGS. 18A and 18B, a second laser drilling process may be performed on the lower molding layer 117 to form the through holes 119 on the line openings H. The through holes 119 may be formed on the line openings H to overlap the line openings H. Each of the through holes 119 may have a diameter L10 less than a length of the long axis of each of the line openings H. Thus, the line openings H may extend beyond side surfaces of the through holes 119. The through holes 119 may be disposed spaced apart from each other.

For example, the through holes 119 may have a spaced distance L1 of about 5 μm to about 100 μm. Each of the through holes 119 overlapping the line openings H may have a phi (φ) shape that is inclined in the third direction (D3).

Thereafter, as shown in FIG. 1B, the upper package 500 may be stacked on the lower package 100. The upper connection 519 of the upper package 500 may be inserted into the through hole 119 having the line openings H. The reflowing process may be performed to expand the upper connection 519 into the through hole 119 and to couple the upper connection 519 to the lower connection 113. Therefore, the semiconductor package 1000 in which the electrical connection 200 is formed in the through hole 119 may be formed.

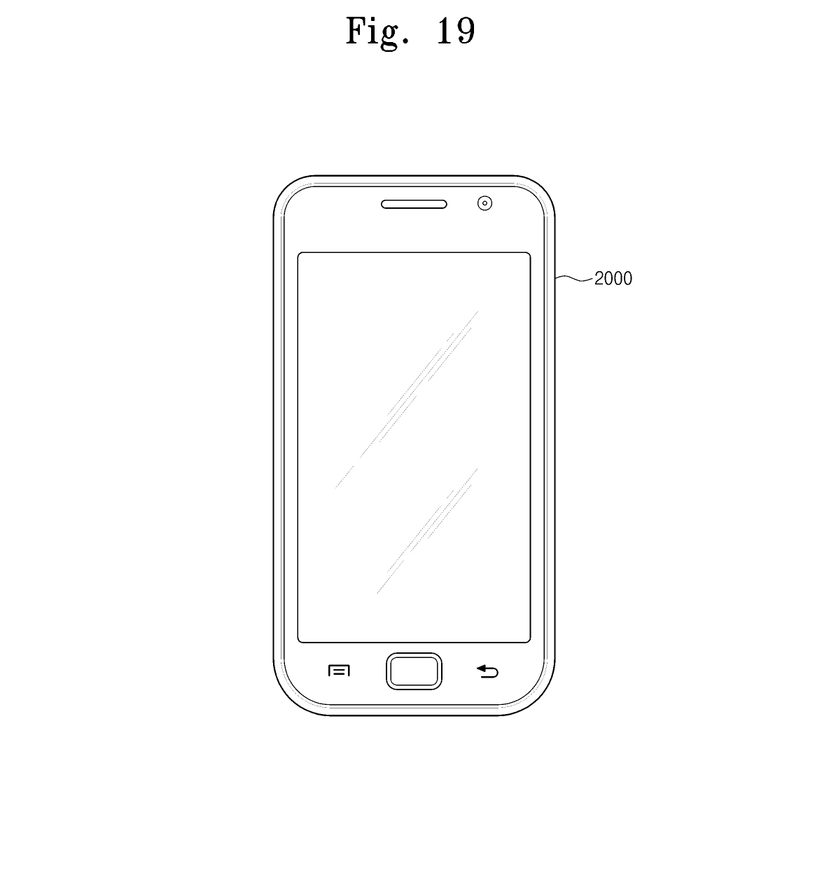

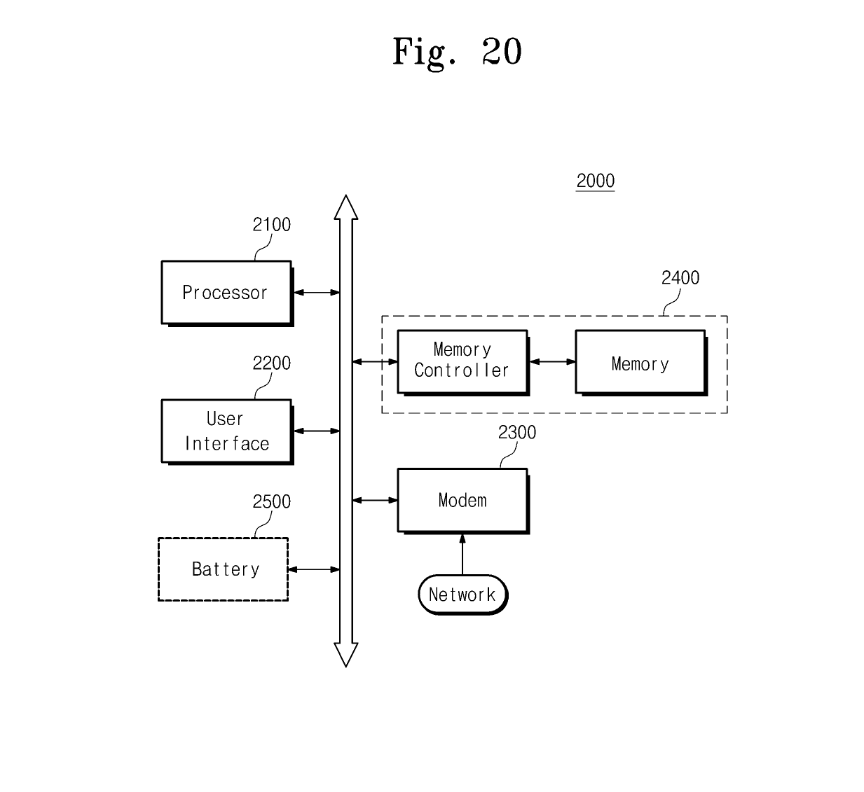

FIG. 19 is a view illustrating an electronic device to which the lamination type semiconductor packages according to the embodiments are applied. FIG. 20 is a schematic block diagram illustrating an electronic device to which the lamination type semiconductor packages according to the embodiments are applied.

FIG. 19 illustrates a mobile phone 2000 according to the embodiments to which the lamination type semiconductor package is applied. For another example, the lamination type semiconductor package according to the embodiments may be applied to smart phones, personal digital assistants (PDAs), portable multimedia players (PMPs), digital multimedia broadcasts (DMBs), global positioning systems (GPSs), handled gaming consoles, portable computers, web tablets, wireless phones, digital music players, memory cards, devices capable of transferring and/or receiving information in wireless environment, or the like.

Referring to FIG. 20, an electrical apparatus 2000 according to some embodiments includes a processor 2100, a user interface 2200, a modem 2300 such as a baseband chipset, and a lamination type semiconductor package 2400 according to an embodiment described herein.

If the electrical apparatus according to the inventive concept is a mobile device, a battery 2500 for supplying power to the electrical apparatus 2000 may be additionally provided. Further, although not shown, an application chipset, a camera image processor (CIS), or the like may be provided in the electrical apparatus 2000 in an embodiment.

In some embodiments, in the method of fabricating the semiconductor package, the first laser drilling process may be performed on the lower connection covered with the lower molding layer to form the first openings facing each other in the third direction that is diagonal direction of the lower connection. Also, the second laser drilling process may be performed on the lower molding layer to form the second openings between the first openings, thereby exposing the lower connection. Thus, the second openings may be formed to overlap the first openings, and thus the through holes defining the first and second openings may increase in volume, thereby preventing short circuit from occurring when the upper package is connected to the lower package.

In an embodiment a semiconductor package may have an improved reliability. Another embodiment includes a method of fabricating a semiconductor package with improved reliability.

Embodiments are not limited to the particular embodiments described herein, but other features not described herein will be clearly understood by those skilled in the art from descriptions below.

Some embodiments include semiconductor package devices including: a lower semiconductor package including a lower semiconductor chip mounted on a lower package substrate and a lower molding layer covering the lower semiconductor chip and having through holes arranged around the lower semiconductor chip in a first direction and a second direction perpendicular to the first direction; an upper semiconductor package including an upper semiconductor chip, the upper semiconductor package being stacked on the lower package substrate; and electrical connections respectively disposed in the through holes to connect the lower semiconductor package to the upper semiconductor package, wherein an upper width of each of the through holes in the first and second directions may be less than that of each of the through holes in the third direction that is a diagonal direction with respect to the first and the second directions.

In some embodiments, the lower semiconductor packages may further include external terminals attached to a bottom surface of the lower semiconductor substrate, chip bumps disposed between chip pads disposed on a top surface of a central portion of the lower semiconductor and the lower semiconductor chip, and a lower connection pad disposed on a top surface of an edge of the lower semiconductor substrate, and the upper semiconductor package may further include a bonding wire connecting a bonding pad disposed on the upper semiconductor chip to a wire pad disposed on a top surface of the upper package substrate, an upper molding layer fully covering the upper semiconductor chip, and an upper connection pad disposed on a bottom surface of the upper semiconductor substrate to face to the lower connection pad.

In other embodiments, each of the electrical connections may include lower and upper connections, wherein the lower connection may contact the lower connection pad, and the upper connection may contact the upper connection pad.

In still other embodiments, the lower molding layer may include protrusions facing each other in the third direction on both sides of each of the through holes.

In even other embodiments, the lower molding layer may include protrusions facing each other in the third direction and a fourth direction perpendicular to the third direction on both sides of each of the through holes.

In yet other embodiments, the lower molding layer may include protrusions protruding from a side of each of the through holes in the third direction.

In further embodiments, sidewalls of the through holes may be spaced apart from the electrical connections, respectively.

In still further embodiments, sidewalls of the through holes may contact the electrical connections, respectively.

In even further embodiments, a bottom surface of each of the through holes may have a width less than the upper width of each of the through holes.

In other embodiments, methods of fabricating semiconductor packages include: forming a molding layer on a lower package substrate on which a semiconductor chip is mounted, wherein the lower package substrate may include lower connections arranged in a first direction and a second direction perpendicular to the first direction to surround the semiconductor chip; performing a first laser drilling process on the molding layer to form first openings which are disposed in at least one side of the lower connections to face each other in a third direction that is a diagonal direction with respect to the first and second directions to pass through a portion of the molding layer; and performing a second laser drilling process between the first openings to overlap the first openings to form second openings exposing the lower connections.

In some embodiments, the first openings may be formed so that top surfaces of the lower connections are not exposed.

In other embodiments, the first openings may be disposed in both sides of each of the lower connections, and in the forming of the first openings, the shortest distance between the first openings may be equal to or less than a diameter of each of the lower connections in the third direction, and the longest distance between the first openings may be greater than a diameter of each of the lower connections in the third direction.

In still other embodiments, the first openings may be formed to across the lower connections in the third direction.

In even other embodiments, the second openings may have a spaced distance of about 5 μm to about 100 μm therebetween.

In yet other embodiments, the methods may further include disposing upper connections attached to a bottom surface of an upper semiconductor package including a semiconductor chip in the second openings to couple the lower connections to the upper connections after the second openings are formed.

The above-disclosed subject matter is to be considered illustrative and not restrictive, and the appended claims are intended to cover all such modifications, enhancements, and other embodiments, which fall within the true spirit and scope. Thus, to the maximum extent allowed by law, the scope of the claims is to be determined by the broadest permissible interpretation of the following claims and their equivalents, and shall not be restricted or limited by the foregoing detailed description.

What is claimed is:

1. A semiconductor package comprising:
a lower semiconductor package comprising a lower semiconductor chip mounted on a lower package substrate and a lower molding layer substantially covering the lower semiconductor chip and having through holes arranged in a first direction and a second direction;
wherein:
the first direction is different from the second direction; and
for each of the through holes, first and second upper widths of the through hole in the first and second directions are less than a third upper width of the through hole in a third direction that is a diagonal direction with respect to the first and second directions.

2. The semiconductor package of claim 1, wherein the first direction and the second direction are substantially perpendicular.

3. The semiconductor package of claim 1, further comprising:
an upper semiconductor package comprising an upper semiconductor chip, the upper semiconductor package being stacked on the lower package substrate; and
electrical connections respectively disposed in the through holes to electrically connect the lower semiconductor package to the upper semiconductor package.

4. The semiconductor package of claim 3, wherein
the lower semiconductor package further comprises external terminals attached to a bottom surface of the lower package substrate, chip bumps disposed between chip pads disposed at a top surface the lower package substrate and the lower semiconductor chip, and a lower connection pad disposed at the top surface of the lower package substrate, and
the upper semiconductor package further comprises a bonding wire connecting a bonding pad disposed at the upper semiconductor chip to a wire pad disposed at a top surface of an upper package substrate of the upper semiconductor package, an upper molding layer substantially covering the upper semiconductor chip, and an upper connection pad disposed on a bottom surface of the upper package substrate disposed to face to the lower connection pad.

5. The semiconductor package of claim 4, wherein each of the electrical connections comprises lower and upper connections, wherein the lower connection contacts the lower connection pad, and the upper connection contacts the upper connection pad.

6. The semiconductor package of claim 3, wherein sidewalls of the through holes are spaced apart from the electrical connections, respectively.

7. The semiconductor package of claim 3, wherein sidewalls of the through holes contact the electrical connections, respectively.

8. The semiconductor package of claim 1, wherein the lower molding layer comprises protrusions disposed along the third direction on opposite sides of each of the through holes.

9. The semiconductor package of claim 8, wherein the lower molding layer comprises protrusions disposed along a fourth direction substantially perpendicular to the third direction on opposite sides of each of the through holes.

10. The semiconductor package of claim 1, wherein the lower molding layer comprises protrusions protruding in the third direction from a side of each of the through holes.

11. The semiconductor package of claim 1, wherein for each of the through holes, a bottom width of the through hole is less than the upper width of the through hole.

12. A method of fabricating a semiconductor package, the method comprising:
forming a molding layer on a lower package substrate on which a lower semiconductor chip is mounted, wherein the lower package substrate comprises lower connections arranged in a first direction and a second direction different from the first direction;
forming first openings associated with the lower connections in the molding layer, each first opening disposed along a third direction relative to the corresponding lower connection that is a diagonal direction with respect to the first and second directions; and
forming second openings exposing the lower connections, each first opening overlapping the second opening exposing the corresponding lower connection.

13. The method of claim 12, wherein the first openings are formed so that top surfaces of the lower connections are not exposed.

14. The method of claim 12, wherein:
the first openings are disposed on opposite sides of the corresponding lower connection; and
in the forming of the first openings, a shortest distance between the first openings is equal to or less than a diameter of the corresponding lower connection in the third direction, and a longest distance between the first openings is greater than the diameter of the corresponding lower connection in the third direction.

15. The method of claim 12, wherein the first openings are formed on opposite sides of the corresponding lower connection in the third direction.

16. The method of claim 12, wherein a distance between the second openings is about 5 μm to about 100 μm.

17. The method of claim 12, further comprising disposing upper connections attached to a bottom surface of an upper semiconductor package comprising an upper semiconductor chip in the second openings to couple the lower connections to the upper connections after the second openings are formed.

18. A semiconductor package, comprising:
a package substrate including a plurality of connection pads;
a molding layer disposed on the package substrate; and
a plurality of through holes in the molding layer exposing corresponding connection pads, each through hole comprising:
a first opening; and
a second opening;
wherein the first opening is disposed along a side surface of the second opening and extends along less than all of the side surface of the second opening.

19. The semiconductor package of claim 18, wherein each through hole further comprises a third opening disposed along the side surface of the second opening and substantially opposite the first opening.

20. The semiconductor package of claim 18, wherein for each through hole, the first opening is disposed at a position along the side surface of the second opening such that a minimum distance from the first opening to an adjacent second opening is a local maximum.
